(19) United States
(12) Patent Application Publication
(10) Pub. No.: US 2026/0082532 A1
(43) Pub. Date: Mar. 19, 2026

(54) SEMICONDUCTOR STRUCTURE AND METHOD FOR FORMING THE SAME

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/889,228

(22) Filed: Sep. 18, 2024

(51) Int. Cl. H10B 10/00; H01L 29/06; H01L 29/417; H01L 29/423; H01L 29/66; H01L 29/775; H01L 29/786

(52) U.S. Cl. CPC H10B 10/125; H10D 30/014; H10D 30/43; H10D 30/6729; H10D 30/6735; H10D 30/6757; H10D 62/121

(57) ABSTRACT

A semiconductor structure includes a first cell and a second cell, a first metal line, and a second metal line. The first cell and the second cell are over the substrate and arranged along a first direction, wherein the first cell comprises first transistors arranged along a second direction substantially perpendicular to the first direction, and the second cell comprises second transistors arranged along the second direction, and wherein gate structures of the first transistors and gate structures of the second transistors extend along the first direction. The first metal line is electrically connected with a source/drain region of a first one of the first transistors and a source/drain region of a first one of the second transistors. A second metal line is electrically connected with a source/drain region of a second one of the first transistors and a source/drain region of a second one of the second transistors.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a static random access memory (SRAM) cell, in accordance with some embodiments of the disclosure.

FIG. 1B illustrates a simplified diagram of the memory cell of FIG. 1A, in accordance with some embodiments of the present disclosure.

FIGS. 2A to 2D illustrate a layout of a semiconductor structure, in accordance with some embodiments of the present disclosure.

FIGS. 3A to 3H illustrate cross-sectional views along reference cross-sections C1-C1′, C2-C2′, C3-C3′, C4-C4′, C5-C5′, C6-C6′, C7-C7′ and C8-C8′ in FIGS. 2A to 2D, respectively.

FIGS. 4A through 8B illustrate schematic views of intermediate stages in the formation of a memory device in accordance with some embodiments.

FIG. 9 illustrates a layout of a memory device, in accordance with some embodiments of the present disclosure.

FIGS. 10A and 10B illustrate cross-sectional views along reference cross-sections C3-C3′ and C7-C7′ in FIG. 9, respectively.

FIGS. 11A and 11B illustrate a layout of a memory device, in accordance with some embodiments of the present disclosure.

FIGS. 12A to 12F illustrate cross-sectional views along reference cross-sections C1-C1′, C2-C2′, C3-C3′, C4-C4′, C5-C5′, and C8-C8′ in FIGS. 11A and 11B, respectively.

FIGS. 13A and 13B illustrate a layout of a memory device, in accordance with some embodiments of the present disclosure.

FIGS. 14A and 14B illustrate cross-sectional views along reference cross-sections C2-C2′ and C7-C7′ in FIGS. 13A and 13B, respectively.

FIG. 15 illustrates a layout of a memory device, in accordance with some embodiments of the present disclosure.

FIG. 16 illustrates a cross-sectional view along reference cross-section C1-C1′ in FIG. 15.

FIG. 17 illustrates a layout of a memory device, in accordance with some embodiments of the present disclosure.

FIG. 18 illustrates a layout of a memory device, in accordance with some embodiments of the present disclosure.

FIG. 19 illustrates a cross-sectional view along reference cross-sections C5-C5′ in FIG. 18.

FIG. 20 illustrates a layout of a memory device, in accordance with some embodiments of the present disclosure.

FIG. 21 illustrates a cross-sectional view along reference cross-sections C3-C3′ in FIG. 20.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices including improved isolation structures to reduce current leakage from channels to the substrate. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel layers (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments discussed herein are discussed in the context of nano-FETs formed using a gate-last process. In other embodiments, a gate-first process may be used. Also, some embodiments contemplate aspects used in planar devices, such as planar FETs, or in fin field-effect transistors (FinFETs). For example, FinFETs may include fins on a substrate, with the fins acting as channel regions for the FinFETs. Similarly, planar FETs may include a substrate, with portions of the substrate acting as channel regions for the planar FETs.

In the course of IC evolution, functional density (i.e., the number of interconnected devices per chip area) has generally increased while geometry size (i.e., the smallest component (or line) that can be created using a fabrication process) has decreased. However, the smaller and more dense the metal lines in the IC structure will result in worse resistant thereof, thereby wasting processing power and processing speed during the operation of the IC structure. For example, static random access memory (SRAM) bit-lines may be disposed in a metallization layer. However, when metal thickness and line width are continuous shrunk, the metal may push the metal pitch to limitation for logic circuit routing density improvement, which in turn leads to increased resistance in both SRAM bit-line and Vss conductors (IR drop concern), and therefore impact the cell speed and V_min performance.

Therefore, the present disclosure in various embodiments provides a SRAM array may include plurality of grouped memory cells in word-line routing direction, and each grouped cell may include two adjacent cells that placed in word-line routing direction and shared one bit-line pair. The merged two SRAM cells with one bit-line pair allows for a wider width for the bit line, which in turn allows for a decrease in resistance and an increase in array size (i.e., more columns and rows) for capacitance reduction.

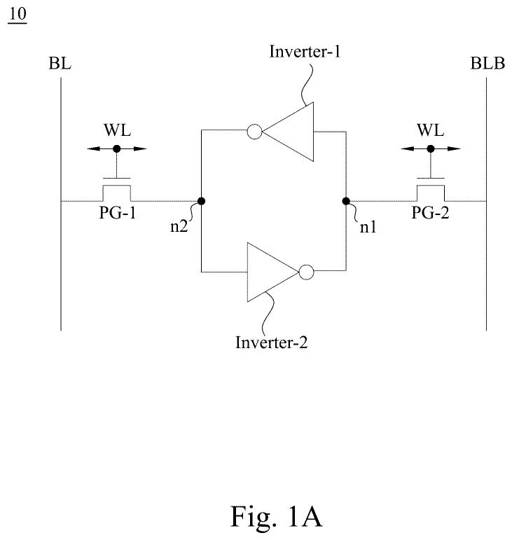

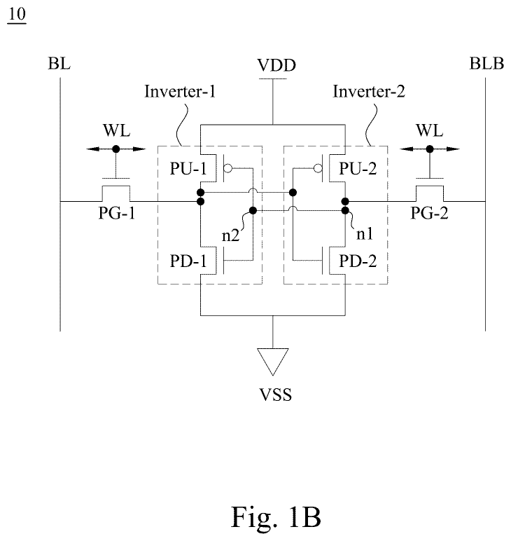

Reference is made to FIGS. 1A and 1B. FIGS. 1A and 1B illustrates a circuit diagram of a static random access memory (SRAM) cell 10 in accordance with some embodiments of the present disclosure. FIG. 1A illustrates a SRAM cell 10, in accordance with some embodiments of the disclosure. FIG. 1B illustrates a simplified diagram of the memory cell 10 of FIG. 1A, in accordance with some embodiments of the present disclosure. In one or more embodiments of the present disclosure, the memory cell 10 as illustrated in FIGS. 1A and 1B may be a single-port SRAM cell.

As illustrated in FIG. 1A, the memory cell 10 may include a pair of cross-coupled inverters Inverter-1 and Inverter-2 and two pass-gate transistors PG-1 and PG-2. The inventers Inventer-1 and Inventer-2 are cross-coupled between the nodes n1 and n2, and form a latch circuit. In some embodiments, one of the nodes n1 and n2 is used as an output terminal of the latch circuit and the other node is used as in input terminal of the latch circuit. The pass-gate transistor PG-1 is coupled between a bit line BL and the node n2, and the pass-gate transistor PG-2 is coupled between a complementary bit line BLB and the node n1, wherein the complementary bit line BLB is complementary to the bit line BL. The gates of the pass-gate transistors PG-1 and PG-2 are coupled to the same word line WL. Furthermore, in some embodiments, the pass-gate transistors PG-1 and PG-2 are NMOS transistors. In some embodiments, the memory cell 10 may include two isolation transistors, wherein the sources of the isolation transistors are floating and the gates and the drains of one of the isolation transistors are coupled to one of the nodes n1 and n2. In some embodiments, the isolation transistors may be PMOS transistors.

FIG. 1B shows a simplified diagram of the memory cell of FIG. 1A, in accordance with some embodiments of the present disclosure. The inverter Inverter-1 includes a pull-up transistor PU-1 and a pull-down transistor PD-1. The pull-up transistor PU-1 may be a PMOS transistor, and the pull-down transistor PD-1 may be an NMOS transistor. The drain of the pull-up transistor PU-1 and the drain of the pull-down transistor PD-1 are coupled to the node n2 connecting the pass-gate transistor PG1. The gates of the pull-up transistor PU-1 and the pull-down transistor PD1 are couple to the node n1 connecting the pass-gate transistor PG-2. Furthermore, the source of the pull-up transistor PU-1 is coupled to the power supply VDD, and the source of the pull-down transistor PD-1 is coupled to a ground VSS.

Similarly, the inverter Inverter-2 includes a pull-up transistor PU-2 and a pull-down transistor PD-2. The pull-up transistor PU-2 may be a PMOS transistor, and the pull-down transistor PD-2 may be a NMOS transistor. The drains of the pull-up transistor PU-2 and the pull-down transistor PD-2 are coupled to the node n1 connecting the pass-gate transistor PG-2. The gates of the pull-up transistor PU-2 and the pull-down transistor PD-2 are coupled to the node n1 connecting the pass-gate transistor PG-1. Furthermore, the source of the pull-up transistor PU-2 is coupled to the power supply VDD, and the source of the pull-down transistor PD-2 is coupled to the ground VSS.

In some embodiments that the memory cell 10 includes two isolation transistors, the drain and the gate of one of the isolation transistors are both coupled to the node n2 and the drain and the gate of another one of the isolation transistors are both coupled to the node n1. The sources of the isolation transistors are depicted as flowing. In some embodiments, the sources of the isolation transistors may be coupled to respective transistors in adjacent memory cells.

In some embodiments, the pass-gate transistors PG-1 and PG-2, the pull-up transistors PU-1 and PU-2, the pull-down transistors PD-1 and PD-2, and the isolation transistors of the memory cells 10 may be gate all around (GAA) FETs.

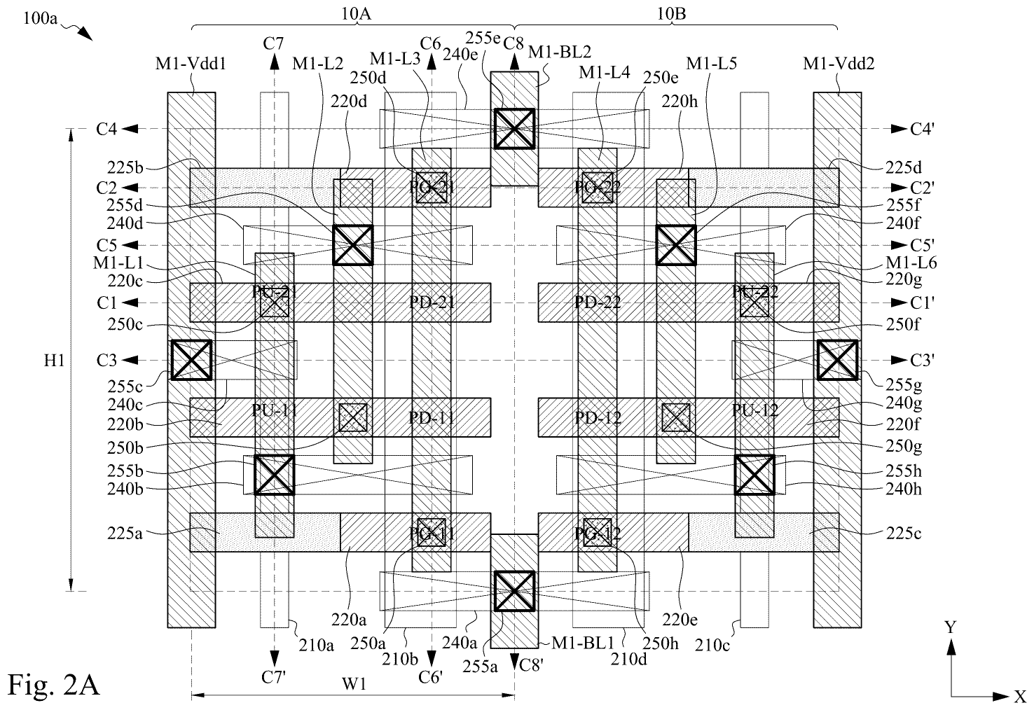

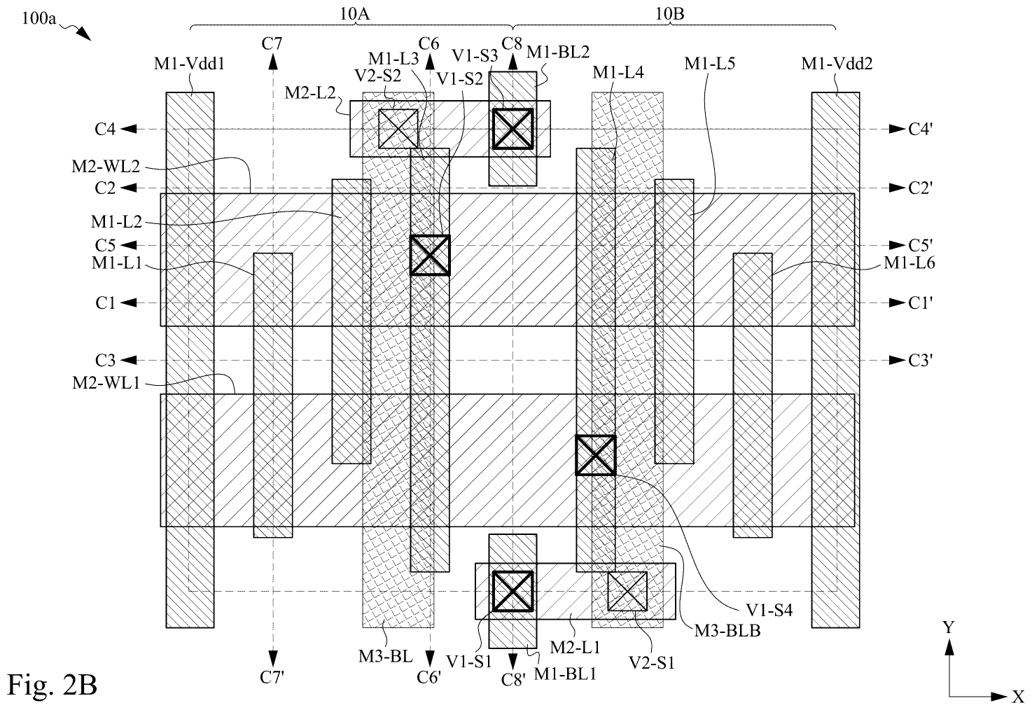

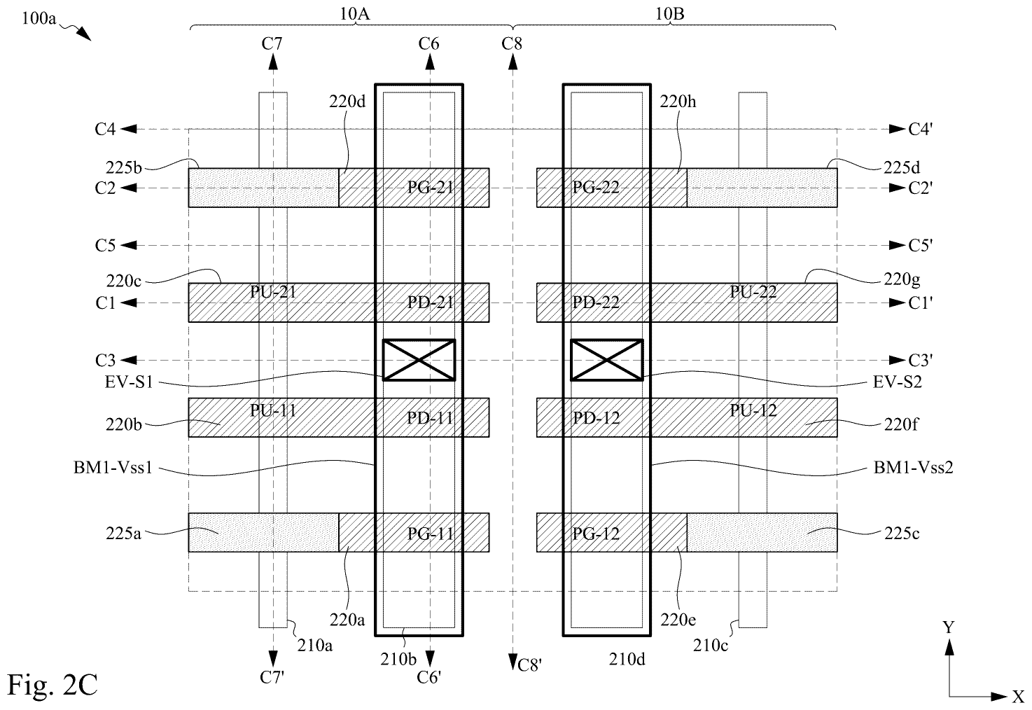

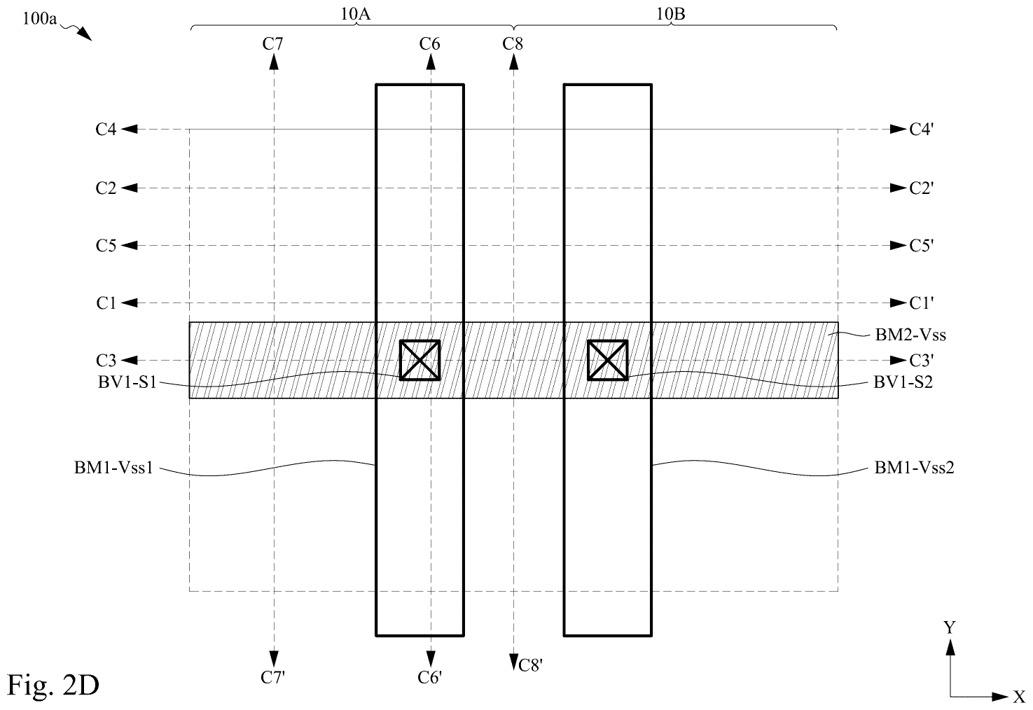

FIGS. 2A to 2D illustrate a layout of a semiconductor structure, in accordance with some embodiments of the present disclosure. In greater detail, the semiconductor structure shown in FIGS. 2A to 2D illustrates several elements of a memory device 100a at different levels. For example, FIGS. 2A and 2B illustrate elements of the memory device 100a at a front side of a substrate (e.g., the substrate 105), and FIGS. 2C and 2D illustrate elements of the memory device 100a at a back side of the substrate (e.g., the substrate 105).

The memory device 100a includes memory cells 10A and 10B arranged along the X-direction. Each of the memory cells 10A and 10B corresponds to a single-port SRAM bit cell of the memory cell 10 of FIGS. 1A and 1B. For example, the memory cell 10A includes transistors PG-11, PG-21, PD-11, PD-21, PU-11 and PU-21, and the memory cell 10B includes transistors PG-12, PG-22, PD-12, PD-22, PU-12 and PU-22, respectively. The memory cells 10A and 10B can be implemented in a memory of an IC. The outer boundaries of the memory cells 10A and 10B is illustrated using dashed lines. Furthermore, each of the memory cells 10A and 10B has a cell width W1 (or X-pitch) along the X-direction and a cell height H1 (or Y-pitch) along the Y-direction that is substantially perpendicular to the X-direction. In some embodiments, a ratio of the cell height H1 to the cell width W1 can be in a range from about 1.2 to 2.5, such as about 1.2, 1.5, 1.8, 2.1 or 2.5. That is, the cell height H1 is greater than the cell width W1.

The memory device 100a may include a plurality of transistors. In some embodiments, the transistors may be GAA FETs. Each of the transistors may include a plurality of semiconductor channel layers stacked along the Z-direction (not shown), in which the Z-direction is substantially perpendicular to the plane formed by the X-direction and Y-direction. Each of the transistors may also include a gate electrode wrapping around the semiconductor channel layers. Each of the transistors may also include source/drain regions on opposite sides of each of the semiconductor channel layers.

Reference is made to FIG. 2A. With respect to the memory cell 10A, the memory cell 10A includes several semiconductor layers 210a and 210b extending along the Y-direction. In some embodiments, the semiconductor layers 210b may be wider than the semiconductor layers 210a along the X-direction. The memory cell 10A further includes gate electrodes 220a, 220b, 220c and 220d extending along the X-direction and parallel with each other. The memory cell 10A further includes a dielectric gate 225a in contact with the gate electrode 220a and a dielectric gate 225b in contact with the gate electrode 220d, in which the dielectric gates 225a and 225b may extend along the X-direction. In some embodiments, the dielectric gates 225a and 225b can be made of silicon oxide (SiOx), silicon nitride (SixNy), silicon oxynitride (SiON), dielectric material(s), other suitable material, or a combination thereof.

The gate electrodes 220a, 220b, 220c and 220d may form a plurality of transistors with the semiconductor layers 210a and 210b, respectively. The gate electrode 220a forms a pass-gate transistor PG-11 with the underlying semiconductor layers 210b. The gate electrode 220b forms a pull-down transistor PD-11 with the underlying semiconductor layers 210b. The gate electrode 220b forms a pull-up transistor PU-11 with the underlying semiconductor layers 210a. The gate electrode 220c forms a pull-down transistor PD-21 with the underlying semiconductor layers 210b. The gate electrode 220c forms a pull-up transistor PU-21 with the underlying semiconductor layers 210a. The gate electrode 220d forms a pass-gate transistor PG-21 with the underlying semiconductor layers 210b. The pull-up transistors PU-11 and PU-21 are between the dielectric gates 225a and 225b along the Y-direction. In other words, the transistors PU-11 and PU-21 may share the same semiconductor layers 210a, and the transistors PG-11, PD-11, PD-21 and PG-21 may share the same semiconductor layers 210b. The transistors PG-11, PG-21, PD-11, PD-21, PU-11 and PU-21 of the memory cell 10A may respectively correspond to the transistors PG-1, PG-2, PD-1, PD-2, PU-1 and PU-2 of the memory cell 10 as illustrated in FIG. 1B.

On the other hand, with respect to the memory cell 10B, the memory cell 10B includes several semiconductor layers 210c and 210d extending along the Y-direction. In some embodiments, the semiconductor layers 210d may be wider than the semiconductor layers 210c along the X-direction. In some embodiments, the semiconductor layers 210c may include a same width as the semiconductor layers 210a along the X-direction, and the semiconductor layers 210d may include a same width as the semiconductor layers 210b along the X-direction. The memory cell 10B further includes gate electrodes 220e, 220f, 220g, and 220h extending along the X-direction and parallel with each other. In some embodiments, the gate electrode 220e may be aligned with the gate electrode 220a along the X-direction, the gate electrode 220f may be aligned with the gate electrode 220b along the X-direction, the gate electrode 220g may be aligned with the gate electrode 220c along the X-direction, and the gate electrode 220h may be aligned with the gate electrode 220d along the X-direction, respectively. The memory cell 10B further includes a dielectric gate 225c in contact with the gate electrode 220e and a dielectric gate 225d in contact with the gate electrode 220h, in which the dielectric gates 225c and 225d may extend along the X-direction.

Similarly, the gate electrodes 220c, 220f, 220g, and 220h may form a plurality of transistors with the semiconductor layers 210c and 210d, respectively. The gate electrode 220e forms a pass-gate transistor PG-12 with the underlying semiconductor layers 210d. The gate electrode 220f forms a pull-down transistor PD-12 with the underlying semiconductor layers 210d. The gate electrode 220f forms a pull-up transistor PU-12 with the underlying semiconductor layers 210c. The gate electrode 220g forms a pull-down transistor PD-22 with the underlying semiconductor layers 210d. The gate electrode 220g forms a pull-up transistor PU-22 with the underlying semiconductor layers 210c. The gate electrode 220h forms a pass-gate transistor PG-22 with the underlying semiconductor layers 210d. The pull-up transistors PU-12 and PU-22 are between the dielectric gates 225c and 225d along the Y-direction. The transistors PU-12 and PU-22 may share the same semiconductor layers 210c, and the transistors PG-12, PD-12, PD-22 and PG-22 may share the same semiconductor layers 210d. The transistors PG-12, PG-22, PD-12, PD-22, PU-12 and PU-22 of the memory cell 10B may respectively correspond to the transistors PG-1, PG-2, PD-1, PD-2, PU-1 and PU-2 of the memory cell 10 as illustrated in FIG. 1B.

In some embodiments, the semiconductor layers 210a and 210c may include symmetric profiles with respect to the boundary of the memory cells 10A and 10B, and the semiconductor layers 210b and 210d may include symmetric profiles with respect to the boundary of the memory cells 10A and 10B. Similarly, the gate electrodes 220a and 220e may include symmetric profiles with respect to the boundary of the memory cells 10A and 10B, the gate electrodes 220b and 220f may include symmetric profiles with respect to the boundary of the memory cells 10A and 10B, the gate electrodes 220c and 220g may include symmetric profiles with respect to the boundary of the memory cells 10A and 10B, and the gate electrodes 220d and 220h may include symmetric profiles with respect to the boundary of the memory cells 10A and 10B.

The memory device 100a further includes source/drain contacts 240a, 240b, 240c, 240d, 240c, 240f, 240f, and 240h. In some embodiments, the source/drain contacts 240a to 240h are at the same level. The source/drain contact 240a is electrically connected with the source/drain region of the transistor PG-11 and the source/drain region of the transistor PG-12, respectively. Accordingly, the source/drain contact 240a may extend from the memory cell 10A, passing through the boundary of the memory cells 10A and 10B, to the memory cell 10B. The source/drain contact 240b is electrically connected with the source/drain region of the transistor PG-11, the source/drain region of the transistor PU-11, and the source/drain region of the transistor PD-11, respectively. The source/drain contact 240c is electrically connected with the source/drain region of the transistor PU-11 and the source/drain region of the transistor PU-21, respectively. The source/drain contact 240d is electrically connected with the source/drain region of the transistor PU-21, the source/drain region of the transistor PD-21, and the source/drain region of the transistor PG-21, respectively. The source/drain contact 240e is electrically connected with the source/drain region of the transistor PG-21 and the source/drain region of the transistor PG-22, respectively. Accordingly, the source/drain contact 240e may extend from the memory cell 10A, passing through the boundary of the memory cells 10A and 10B, to the memory cell 10B. The source/drain contact 240f is electrically connected with the source/drain region of the transistor PU-22, the source/drain region of the transistor PD-22, and the source/drain region of the transistor PG-22, respectively. The source/drain contact 240g is electrically connected with the source/drain region of the transistor PU-21 and the source/drain region of the transistor PU-22, respectively. The source/drain contact 240h is electrically connected with the source/drain region of the transistor PG-12, the source/drain region of the transistor PU-12, and the source/drain region of the transistor PD-12, respectively.

In some embodiments, the source/drain contact 240a may overlap the semiconductor layers 210b and 210d. The source/drain contact 240b may overlap the semiconductor layers 210a and 210b. The source/drain contact 240c may overlap the semiconductor layers 210a. The source/drain contact 240d may overlap the semiconductor layers 210a and 210b. The source/drain contact 240e may overlap the semiconductor layers 210b and 210d. The source/drain contact 240f may overlap the semiconductor layers 210c and 210d. The source/drain contact 240g may overlap the semiconductor layers 210c. The source/drain contact 240h may overlap the semiconductor layers 210c and 210d.

The memory device 100a further includes gate vias 250a, 250b, 250c, 250d, 250e, 250f, 250g, and 250h, which are at the same level. The gate vias 250a, 250b, 250c, 250d, 250e, 250f, 250g, and 250h may be electrically connected with the gate electrodes 220a, 220b, 220c, 220d, 220h, 220g, 220f, and 220e, respectively. The memory device 100a further includes source/drain vias 255a, 256b, 255c, 255d, 255e, 255f, 255g, and 255h, which are at the same level. The source/drain vias 255a, 255b, 255c, 255d, 255e, 255f, 255g, and 255h may be electrically connected with the source/drain contacts 240a, 240b, 240c, 240d, 240e, 240f, 240g, and 240h, respectively. In some embodiments, the gate vias 250a to 250h and the source/drain vias 255a to 255h are at the same level.

The memory device 100a further includes metal lines M1-Vdd1, M1-L1, M1-L2, M1-L3, M1-BL1, M1-BL2, M1-L4, M1-L5, M1-L6, and M1-Vdd2, which are at the same level. The metal line M1-L1 is electrically connected with the gate via 250c and the source/drain via 255c, such so as to electrically couple the gate electrode 220c of the transistors PU-21 and PD-21 to the source/drain regions of the transistors PU-11, PD-11, and PG-11. The metal line M1-L2 is electrically connected with the gate via 250b and the source/drain via 255d, such so as to electrically couple the gate electrode 220b of the transistors PU-11 and PD-11 to the source/drain regions of the transistors PU-21, PD-21, and PG-21. The metal line M1-L3 is electrically connected with the gate vias 250a and 250d, so as to electrically couple the gate electrode 220a of the transistor PG-11 to the gate electrode 220d of the transistor PG-21. The metal line M1-L4 is electrically connected with the gate vias 250e and 250h, so as to electrically couple the gate electrode 220e of the transistor PG-12 to the gate electrode 220h of the transistor PG-22. The metal line M1-L5 is electrically connected with the gate via 250g and the source/drain via 255f, such so as to electrically couple the gate electrode 220b of the transistors PU-11 and PD-11 to the source/drain regions of the transistors PU-21, PD-21, and PG-21. The metal line M1-L6 is electrically connected with the gate via 250f and the source/drain via 255h, such so as to electrically couple the gate electrode 220g of the transistors PU-22 and PD-22 to the source/drain regions of the transistors PU-12, PD-12, and PG-12. The metal line M1-Vdd1 is electrically connected with the source/drain contact 240c, such that the metal line M1-Vdd1 is electrically coupled to the source/drain regions of the transistors PU-11 and PU-21. Similarly, the metal line M1-Vdd2 is electrically connected with the source/drain contact 240g, such that the metal line M1-Vdd2 is electrically coupled to the source/drain regions of the transistors PU-12 and PU-22. The metal line M1-BL1 is electrically connected with the source/drain contact 240a, so as to electrically couple the source/drain region of the transistor PG-11 and the source/drain region of the transistor PG-12. The metal line M1-BL2 is electrically connected with the source/drain contact 240e, so as to electrically couple the source/drain region of the transistor PG-21 and the source/drain region of the transistor PG-22.

In some embodiments, the metal line M1-Vdd1 may serve as the power rail VDD of the memory cell 10A, and the metal line M1-Vdd2 may serve as the power rail VDD of the memory cell 10B. Accordingly, the metal lines M1-Vdd1 and M1-Vdd2 can also be referred to as power rails M1-Vdd1 and M1-Vdd2. Each of the metal lines M1-Vdd1 and M1-Vdd2 may include a lengthwise direction extending along the Y-direction. In some embodiments, each of the metal lines M1-Vdd1 and M1-Vdd2 may include a length that is greater than the cell height H1 of the memory cells 10A and 10B.

Reference is made to FIG. 2B. In greater detail, FIG. 2B illustrates elements of the memory device 100a that is above the layer of the metal lines M1-Vdd1, M1-L1, M1-L2, M1-L3, M1-BL1, M1-BL2, M1-L4, M1-L5, M1-L6, and M1-Vdd2. That is, elements below the layer of the metal lines M1-Vdd1, M1-L1, M1-L2, M1-L3, M1-BL1, M1-BL2, M1-L4, M1-L5, M1-L6, and M1-Vdd2 are omitted in FIG. 2B for clarity.

The memory device 100a further includes metal vias V1-S1, V1-S2, V1-S3, and V1-S4, which are at the same level. The metal vias V1-S1, V1-S2, V1-S3, and V1-S4 are electrically connected with the metal lines M1-BL1, M1-L3, M1-BL2, and M1-L4, respectively.

The memory device 100a further includes metal lines M2-L1, M2-WL1, M2-WL2, and M2-L2. The metal lines M2-L1, M2-WL1, M2-WL2, and M2-L2 are electrically connected with the metal vias V1-S4, V1-S3, V1-S1, and V1-S2, respectively. As shown in FIGS. 2A and 2B, it can be understood that the metal line M2-WL1 is electrically coupled to the underlying metal line M1-L3 through the metal via V1-S2, such that the metal line M2-WL1 is electrically coupled to the gate electrode 220a of the transistor PG-11 and the gate electrode 220d of the transistor PG-21. Similarly, as shown in FIGS. 2A and 2B, it can be understood that the metal line M2-WL2 is electrically coupled to the underlying metal line M1-L4 through the metal via V1-S4, such that the metal line M2-WL2 is electrically coupled to the gate electrode 220e of the transistor PG-12 and the gate electrode 220h of the transistor PG-22.

In some embodiments, the metal line M2-WL1 may serve as the word line WL of the memory cell 10A, and the metal line M2-WL2 may serve as the word line WL of the memory cell 10B. Accordingly, the metal lines M2-WL1 and M2-WL2 can also be referred to as word lines M2-WL1 and M2-WL2. Each of the metal lines M2-WL1 and M2-WL2 may include a lengthwise direction extending along the X-direction. In some embodiments, each of the metal lines M2-WL1 and M2-WL2 may include a length that is greater than the twice the cell width W1 of the memory cells 10A and 10B. In some embodiments, the each of the metal lines M2-WL1 and M2-WL2 may overlap both the memory cells 10A and 10B.

The memory device 100a further includes metal vias V2-S1 and V2-S2, which are at the same level. The metal vias V2-S1 and V2-S2 are electrically connected with the metal lines M2-L1 and M2-L2, respectively.

The memory device 100a further includes metal lines M3-BL and M3-BLB, which are at the same level. The metal lines M3-BL and M3-BLB are electrically connected with the metal vias V2-S1 and V2-S2, respectively. As shown in FIGS. 2A and 2B, it can be understood that the metal line M3-BL is coupled to the underlying metal line M1-BL2, so as to electrically couple the metal line M3-BL to the source/drain regions of the transistors PG-21 and PG-22. Similarly, ss shown in FIGS. 2A and 2B, it can be understood that the metal line M3-BLB is coupled to the underlying metal line M1-BL1, so as to electrically couple the metal line M3-BLB to the source/drain regions of the transistors PG-11 and PG-12.

In some embodiments, the metal line M3-BL may serve as the bit line BL of the memory cells 10A and 10B, and the metal line M3-BLB may serve as the complementary bit line BLB of the memory cells 10A and 10B. Accordingly, the metal line M3-BL and the metal line M3-BLB can also be referred to as bit line M3-BL and complementary bit line BLB, respectively. As a result, it can be understood that the memory cells 10A and 10B may share the same bit line (e.g., the bit line M3-BL) and the same complementary bit line (e.g., the bit line M3-BLB). Each of the metal lines M3-BL and M3-BLB may include a lengthwise direction extending along the Y-direction. In some embodiments, each of the metal lines M3-BL and M3-BLB may include a length that is greater than the cell height H1 of the memory cells 10A and 10B.

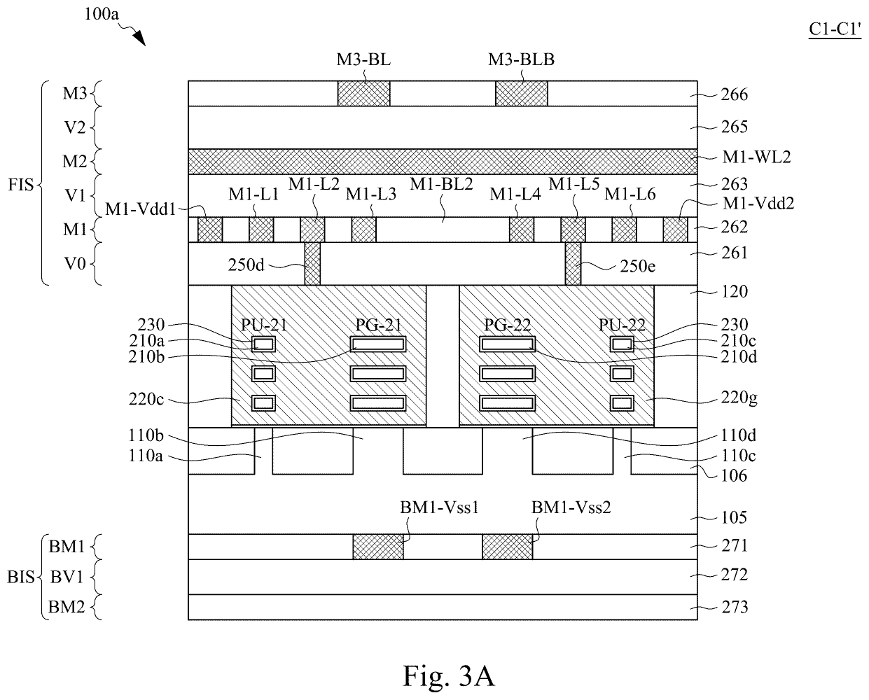

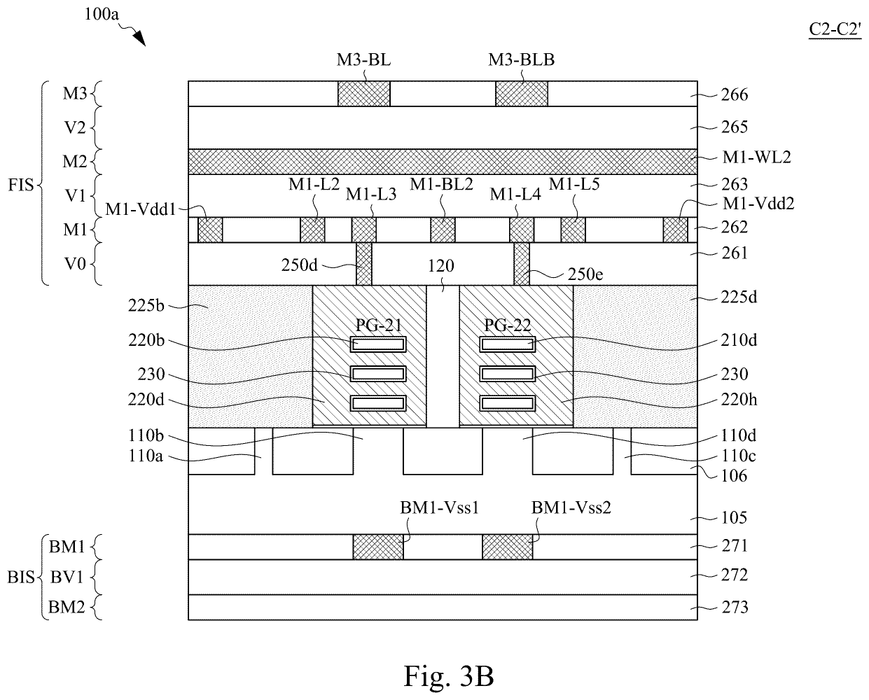

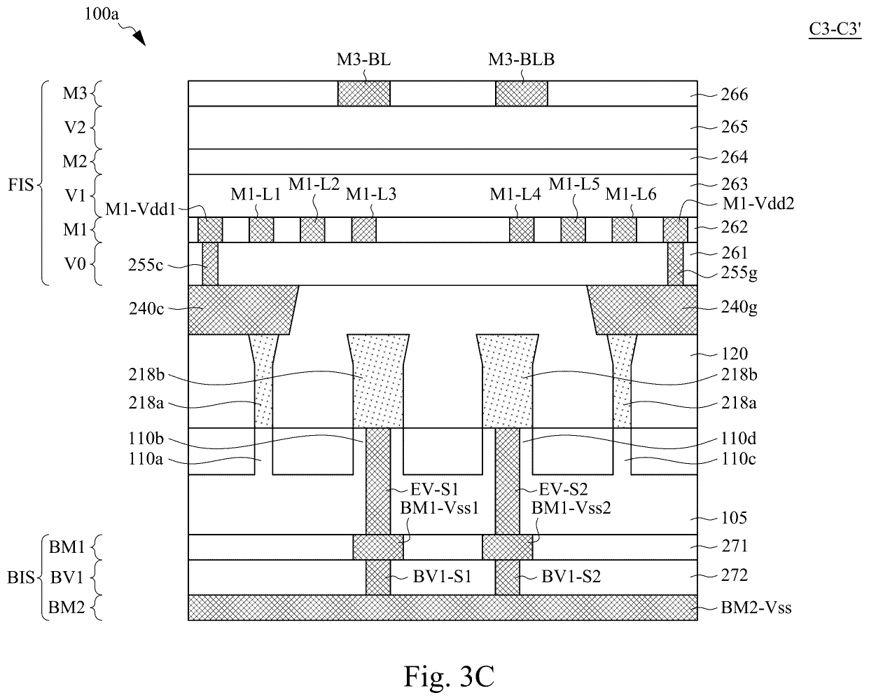

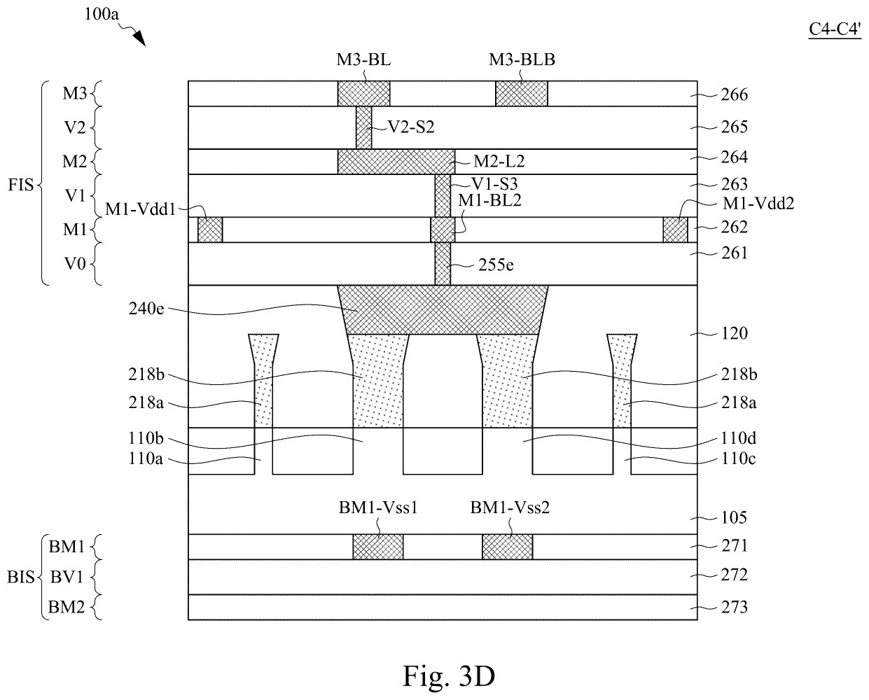

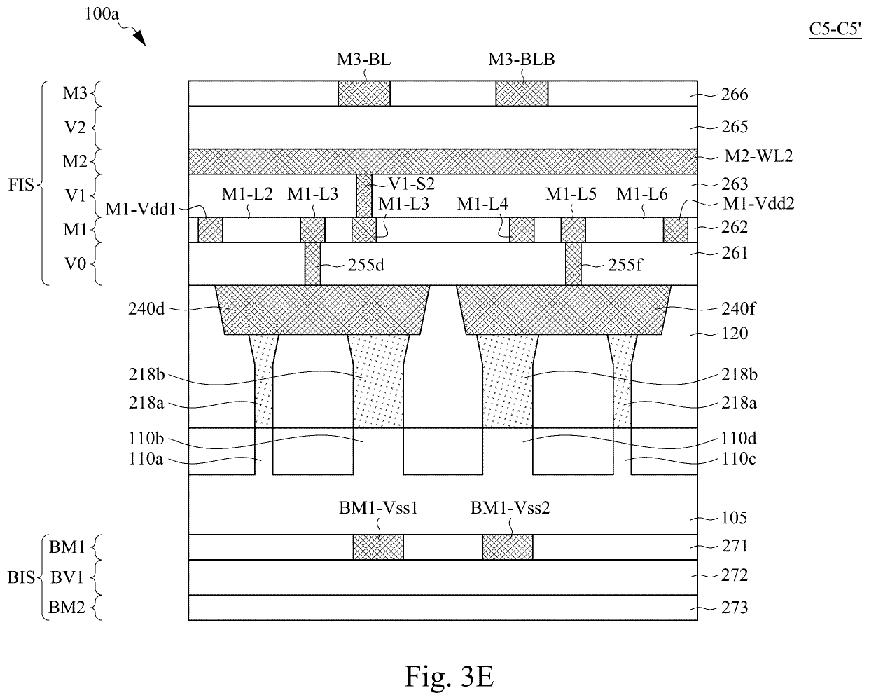

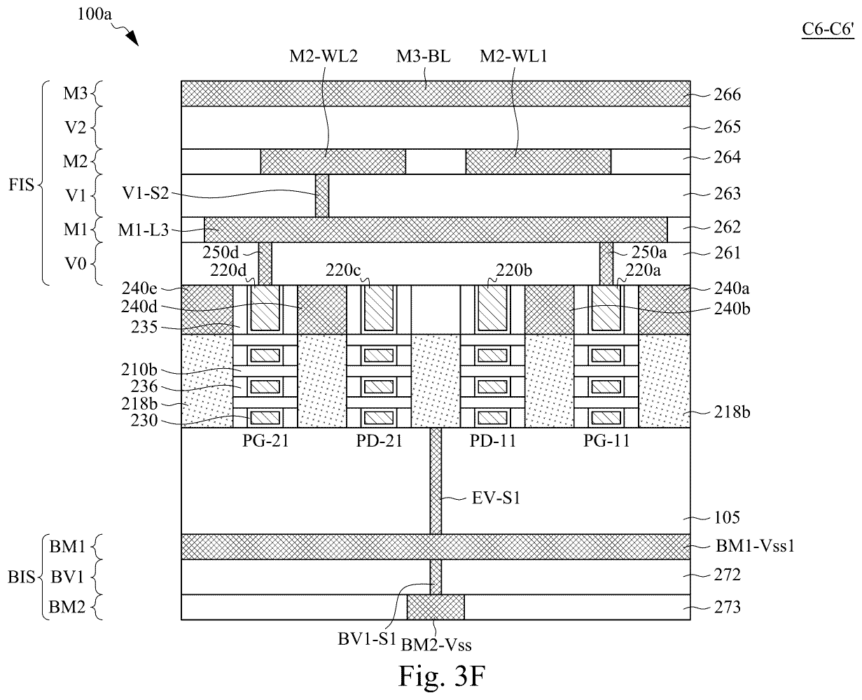

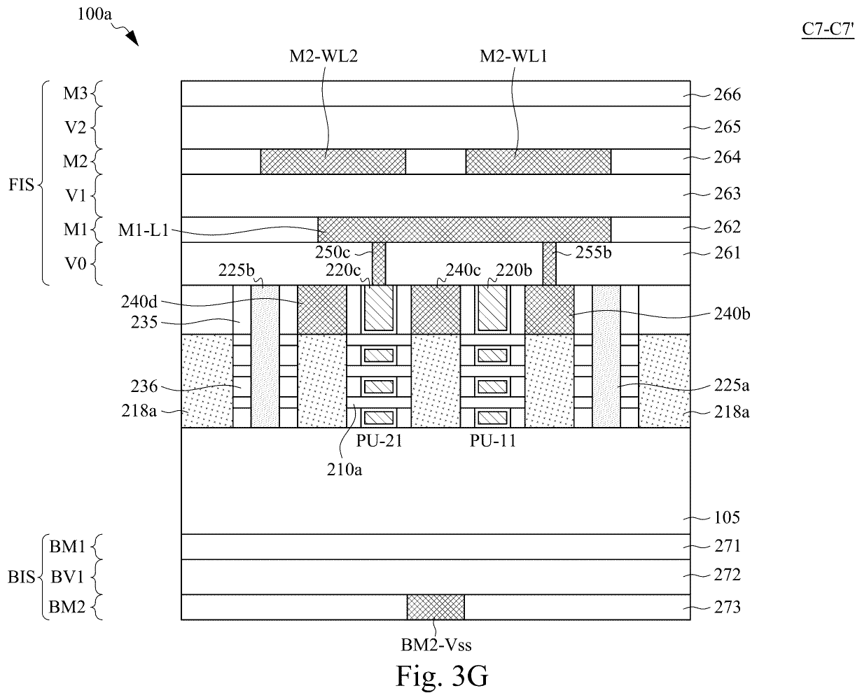

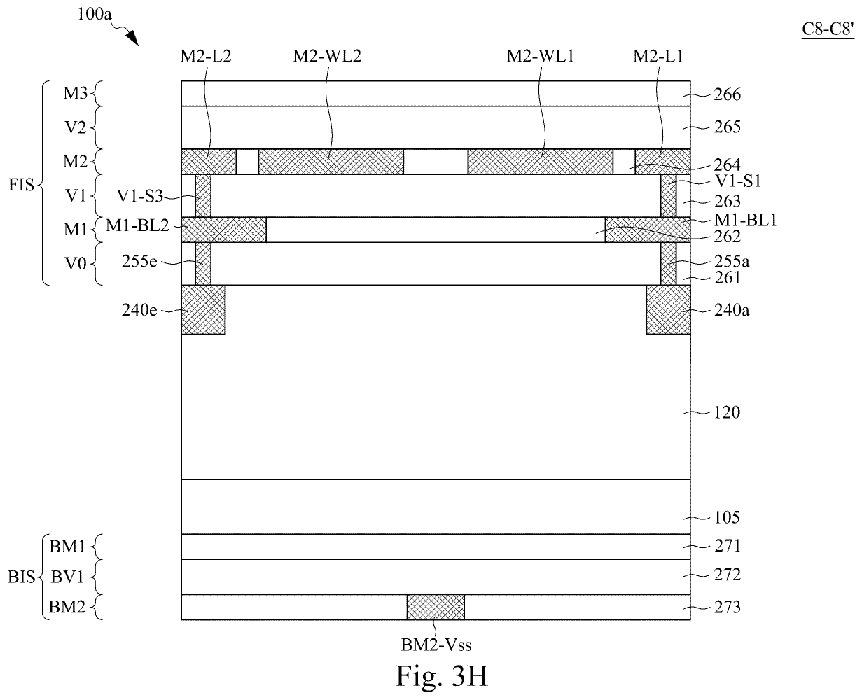

In some embodiments, the metal line M3-BL may overlap the memory cell 10A, and the metal line M3-BLB may overlap the memory cell 10B, respectively. That is, the metal line M3-BL may overlap at least one of the transistors PG-11, PG-21, PD-11, PD-21, PU-11 and PU-21 in the memory cell 10A. In the present embodiments, the metal line M3-BL may overlap the transistors PG-11, PG-21, PD-11, and PD-21 in the memory cell 10A (see FIG. 3F). More specifically, the metal line M3-BL may overlap the gate electrodes 220a, 220b, 220c, and 220d in the memory cell 10A. Similarly, the metal line M3-BLB may overlap at least one of the transistors PG-12, PG-22, PD-12, PD-22, PU-12 and PU-22 in the memory cell 10B. In the present embodiments, the metal line M3-BLB may overlap the transistors PG-12, PG-22, PD-12, and PD-22 in the memory cell 10B (similar to the relationship among the metal line M3-BL and the transistors PG-11, PG-21, PD-11, and PD-21 as shown in FIG. 3F). More specifically, the metal line M3-BLB may overlap the gate electrodes 220e, 220f, 220g, and 220h in the memory cell 10B. In some embodiments, the metal line M3-BL may not overlap the memory cell 10B, and the metal line M3-BLB may not overlap the memory cell 10A. In some embodiments, the metal lines M3-BL and M3-BLB are on opposite sides of the boundary of the memory cells 10A and 10B.

Reference is made to FIG. 2C. In greater detail, FIG. 2C illustrates elements of the memory device 100a that is below the transistors PG-11, PG-21, PD-11, PD-21, PU-11 and PU-21 in the memory cell 10A and the transistors PG-12, PG-22, PD-12, PD-22, PU-12 and PU-22 in the memory cell 10B. That is, elements above the transistors PG-11, PG-21, PD-11, PD-21, PU-11 and PU-21 and the transistors PG-12, PG-22, PD-12, PD-22, PU-12 and PU-22 are omitted in FIG. 2C for clarity.

The memory device 100a further includes metal vias EV-S1 and EV-S2, which are at the same level. The metal via EV-S1 is electrically coupled with the source/drain regions of the transistors PD-11 and PD-21. The metal via EV-S1 is electrically coupled with the source/drain regions of the transistors PD-12 and PD-22.

The memory device 100a further includes metal lines BM1-Vss1 and BM1-Vss2, which are at the same level. The metal lines BM1-Vss1 and BM1-Vss2 are electrically connected with the metal vias EV-S1 and EV-S2, respectively. Accordingly, the metal line BM1-Vss1 is electrically connected with the source/drain regions of the transistors PD-11 and PD-21, and the metal line BM1-Vss1 is electrically connected with the source/drain regions of the transistors PD-12 and PD-22.

Reference is made to FIG. 2D. In greater detail, FIG. 2D illustrates elements of the memory device 100a that is below the layer of the metal lines BM1-Vss1 and BM1-Vss2. That is, elements above the layer of the metal lines BM1-Vss1 and BM1-Vss2 are omitted in FIG. 2D for clarity.

The memory device 100a further includes metal vias BV1-S1 and BV1-S2, which are at the same level. The metal vias BV1-S1 and BV1-S2 are electrically connected with the metal lines BM1-Vss1 and BM1-Vss2, respectively.

The memory device 100a further includes a metal line BM2-Vss. The metal line BM2-Vss is electrically connected with the metal vias BV1-S1 and BV1-S2. That is, the metal lines BM1-Vss1 and BM1-Vss2 are electrically connected with each other through the metal line BM2-Vss.

In some embodiments, the metal line BM1-Vss1 may serve as the power rail VSS of the memory cell 10A, and the metal line BM1-Vss1 may serve as the power rail VSS of the memory cell 10B. Accordingly, the metal lines BM1-Vss1 and BM1-Vss2 can also be referred to as power rails BM1-Vss1 and BM1-Vss2. In some embodiments, because the metal line BM2-Vss electrically couples the metal lines BM1-Vss1 and BM1-Vss2, the power rail VSS of the memory cell 10A and the power rail VSS of the memory cell 10B may be electrically coupled to a same voltage level. In some embodiments, a ground line (e.g., OV) may be applied to the metal line BM2-Vss, and thus the metal lines BM1-Vss1 and BM1-Vss2 can also be referred to as ground lines BM1-Vss1 and BM1-Vss2.

Each of the metal lines BM1-Vss1 and BM1-Vss2 may include a lengthwise direction extending along the Y-direction. In some embodiments, each of the metal lines BM1-Vss1 and BM1-Vss2 may include a length that is greater than the cell height H1 of the memory cells 10A and 10B. In some embodiments, the metal line BM1-Vss1 may not overlap the memory cell 10B, and the metal line BM1-Vss2 may not overlap the memory cell 10A. In some embodiments, the metal lines BM1-Vss1 and BM1-Vss2 are on opposite sides of the boundary of the memory cells 10A and 10B.

The metal line BM2-Vss may include a lengthwise direction extending along the X-direction. In some embodiments, metal line BM2-Vss may include a length that is greater than the twice the cell width W1 of the memory cells 10A and 10B. In some embodiments, the metal line BM2-Vss may overlap both the memory cells 10A and 10B.

Reference is made to FIGS. 2A to 2D and 3A to 3H. FIGS. 3A to 3H illustrate cross-sectional views along reference cross-sections C1-C1′, C2-C2′, C3-C3′, C4-C4′, C5-C5′, C6-C6′, C7-C7′, and C8-C8′ in FIGS. 2A to 2D, respectively. It is noted that some elements shown in FIGS. 3A to 3H have been discussed with respect to FIGS. 2A to 2D, such elements are labeled the same, and relevant details may not be repeated for brevity.

Reference is made to FIGS. 3A to 3H. Shown there is a substrate 105. The substrate 105 may include semiconductor strips 110a, 110b, 110c, and 110d protrude from the top surface of the substrate 105. The semiconductor layers 210a are vertically stacked above the semiconductor strip 110a, the semiconductor layers 210b are vertically stacked above the semiconductor strip 110b, semiconductor layers 210c are vertically stacked above the semiconductor strip 110c, and semiconductor layers 210d are vertically stacked above the semiconductor strip 110d.

Isolation structures 106 can be formed over the substrate 105 and laterally surround the semiconductor strips 110a, 110b, 110c, and 110d. In some embodiments, the isolation structures 106 can also be referred to as shallow trench isolation (STI) structures. In the depicted embodiments, the top surfaces of the isolation structures 106 may be substantially level with top surfaces of the semiconductor strips 110a, 110b, 110c, and 110d. However, in other embodiments, the top surfaces of the isolation structures 106 may be higher than or lower than the top surfaces of the semiconductor strips 110a, 110b, 110c, and 110d. In some embodiments, the isolation structures 106 may be used to electrically isolate the features of adjacent devices.

An interlayer dielectric (ILD) layer 120 is disposed over the substrate 105 and laterally surrounds the gate electrodes 220c and 220g. Although not illustrated in FIG. 3A, the ILD layer 120 may also surround the gate electrodes 220a to 220h as discussed in FIGS. 2A to 2D.

Each of the semiconductor layers 210a, 210b, 210c, and 210d are wrapped by gate dielectric layers 230. Moreover, the semiconductor layers 210a and 210b are wrapped by the gate electrode 220c, and the semiconductor layers 210c and 210d are wrapped by the gate electrode 220g. Although not illustrated in FIG. 3A, the semiconductor layers 210a may also be wrapped by the gate electrodes 220b and 220c as discussed in FIGS. 2A to 2D, the semiconductor layers 210b may also be wrapped by the gate electrodes 220a to 220d as discussed in FIGS. 2A to 2D, the semiconductor layers 210c may also be wrapped by the gate electrodes 220f and 220g as discussed in FIGS. 2A to 2D, and the semiconductor layers 210d may also be wrapped by the gate electrodes 220e to 220h as discussed in FIGS. 2A to 2D.

The memory device 100a includes a front-side interconnect structure FIS over the ILD layer 120. The front-side interconnect structure FIS includes a layer V0, a layer M1 over the layer V0, a layer V1 over the layer M1, a layer M2 over the layer V1, a layer V2 over the layer M2, and a layer M3 over the layer V2. In some embodiments, the layers V0, M1, V1, M2, V2, and M2 may include dielectric layers 261, 262, 263, 264, and 265, respectively.

The gate vias 250a to 250h and the source/drain vias 255a to 255h as discussed in FIGS. 2A to 2D are at the layer V0 of the front-side interconnect structure FIS and are disposed in the dielectric layer 261. The metal lines M1-Vdd1, M1-L1, M1-L2, M1-L3, M1-BL1, M1-BL2, M1-L4, M1-L5, M1-L6, and M1-Vdd2 as discussed in FIGS. 2A to 2D are at the layer M1 of the front-side interconnect structure FIS and are disposed in the dielectric layer 262. The metal vias V1-S1, V1-S2, V1-S3, and V1-S4 as discussed in FIGS. 2A to 2D are at the layer V1 of the front-side interconnect structure FIS and are disposed in the dielectric layer 263. The metal lines M2-L1, M2-WL1, M2-WL2, and M2-L2 as discussed in FIGS. 2A to 2D are at the layer M2 of the front-side interconnect structure FIS and are disposed in the dielectric layer 264. The metal vias V2-S1 and V2-S2 as discussed in FIGS. 2A to 2D are at the layer V2 of the front-side interconnect structure FIS and are disposed in the dielectric layer 265. The metal lines M3-BL and M3-BLB as discussed in FIGS. 2A to 2D are at the layer M3 of the front-side interconnect structure FIS and are disposed in the dielectric layer 266.

Reference is made to FIGS. 3C, 3D, 3E, 3F, and 3G. Source/drain regions 218a are formed over the semiconductor strips 110a and 110c. Source/drain regions 218b are formed over the semiconductor strips 110b and 110d. In some embodiments, the source/drain regions 218a may serve as the source/drain regions of the transistors PU-11, PU-12, PU-12, and PU-22 as discussed in FIGS. 2A to 2D. On the other hand, the source/drain regions 218b may serve as the source/drain regions of the transistors PG-11, PG-21, PD-11, PD-21, PG-12, PG-22, PD-12, and PD-22 as discussed in FIGS. 2A to 2D. In some embodiments, the source/drain regions 218a may include opposite conductivity type than the source/drain regions 218b. For example, the source/drain regions 218a may be p-type source/drain regions, and the source/drain regions 218b may be n-type source/drain regions.

Reference is made to FIGS. 3C and 3F. The metal vias EV-S1 and EV-S2 are disposed in the substrate 105 and in contact with the source/drain regions 218b, respectively. In some embodiments, the metal vias EV-S1 and EV-S2 may also penetrate through the semiconductor strips 110b and 110d, respectively.

Reference is made to FIGS. 3A to 3H. The memory device 100a includes a back-side interconnect structure BIS is on the back side of the substrate 105. The back-side interconnect structure BIS includes a layer BM1, a layer BV1 below the layer BM1, and a layer BM2 below the layer BV1. In some embodiments, the layers BM1, BV1, and BM2 may include dielectric layers 271, 272, and 273, respectively.

The metal lines BM1-Vss1 and BM1-Vss2 as discussed in FIGS. 2A to 2D are at the layer BM1 of the back-side interconnect structure BIS and are disposed in the dielectric layer 271. The metal vias BV1-S1 and BV1-S2 as discussed in FIGS. 2A to 2D are at the layer BV1 of the back-side interconnect structure BIS and are disposed in the dielectric layer 272. The metal line BM2-Vss as discussed in FIGS. 2A to 2D is at the layer BM2 of the back-side interconnect structure BIS and is disposed in the dielectric layer 273.

Reference is made to FIGS. 3F and 3G. Gate spacers 235 are formed on the sidewalls of the gate electrodes 220a, 220b, 220c, and 220d. Inner spacers 236 can act as isolation features which isolate the source/drain regions 218a from the gate electrodes 220b and 220c, respectively, and isolate the source/drain regions 218b from the gate electrodes 220a to 220d, respectively.

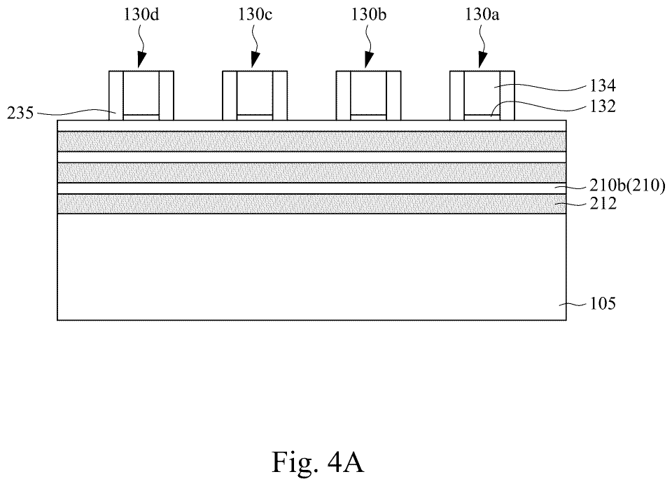

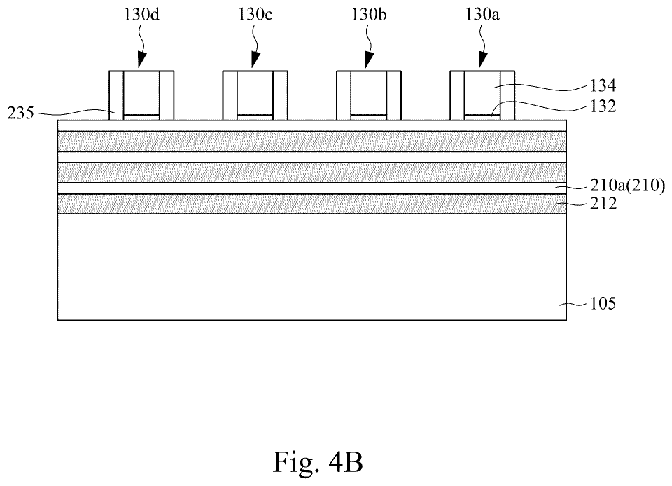

FIGS. 4A to 8B illustrate schematic views of intermediate stages in the formation of a memory device in accordance with some embodiments. In greater detail, FIGS. 4A to 8B show an exemplary method for forming the memory device 100a as discussed above. For brevity, the method as discussed in FIGS. 4A to 8B is discussed with respect to the cross-sectional views of FIGS. 3F and 3G. That is, FIGS. 4A, 5A, 6A, 7A, and 8A may include a same cross-sectional view as FIG. 3F, and FIGS. 4B, 5B, 6B, 7B, and 8B may include a same cross-sectional view as FIG. 3H.

Reference is made to FIGS. 4A and 4B. Stacks of alternating semiconductor layers 210 and sacrificial layers 212 are formed over a substrate 105. In some embodiments, and as will be subsequently described in greater detail, the sacrificial layers 212 will be removed and the semiconductor layers 210 will patterned to form channel layers (e.g., the semiconductor layers 210a to 210d) for the nano-FETs. The sacrificial layers 212 may include a material that has a high etching selectivity from the material of the semiconductor layers 210. In some embodiments, the sacrificial layers 212 may include silicon germanium, and the semiconductor layers 210 may include silicon.

In some embodiments, the stacks of alternating semiconductor layers 210 and sacrificial layers 212 may be patterned, and the patterned semiconductor layers 210 may form the semiconductor layers 210a to 210d as discussed in FIGS. 2A to 2D and 3A to 3H.

Dummy gate structures 130a, 130b, 130c, and 130d may be formed over the stacks of alternating semiconductor layers 210 and sacrificial layers 212. In some embodiments, each of the dummy gate structures 130a, 130b, 130c, and 130d may include a dummy gate dielectric 132 and a dummy gate electrode 134 over the dummy gate dielectric 132. In some embodiments, the dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

Gate spacers 235 are formed on opposite sidewalls of the dummy gate structures 130a, 130b, 130c, and 130d, respectively. In some embodiments, the gate spacers 235 may be made of silicon nitride or silicon oxynitride, although any suitable material, such as low-dielectric constant (low-k) materials having a k-value less than about 3.5, may be utilized.

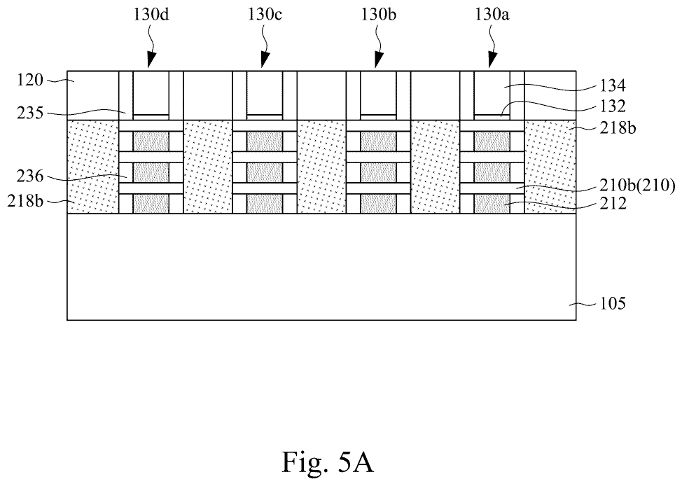

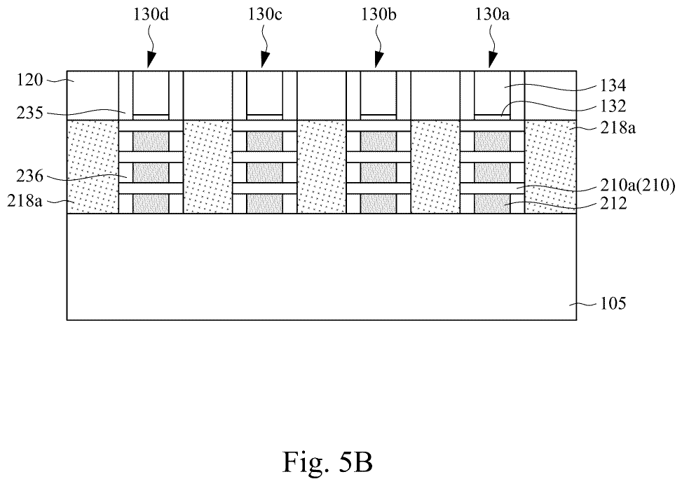

Reference is made to FIGS. 5A and 5B. Portions of the stacks of alternating semiconductor layers 210 and sacrificial layers 212 may be removed by using the dummy gate structures 130a, 130b, 130c, and 130d and the gate spacers 235 as etch mask, so as to form source/drain openings in the stacks of alternating semiconductor layers 210 and sacrificial layers 212.

Afterwards, the sacrificial layers 212 are laterally etched to form sidewall recesses. Inner spacers 236 are then formed in the sidewall recesses. In some embodiments, the inner spacers 236 may be made of silicon nitride or silicon oxynitride, although any suitable material, such as low-dielectric constant (low-k) materials having a k-value less than about 3.5, may be utilized.

Source/drain regions 218a and 218b are then formed in the source/drain openings. The source/drain regions 218a and 218b may be epitaxially grown regions. For example, the source/drain openings may be formed to expose sidewalls of the semiconductor layers 210, a crystalline semiconductor material may be deposited in the source/drain openings by a selective epitaxial growth (SEG) process. The crystalline semiconductor material may be elemental (e.g., Si, or Ge, or the like), or an alloy (e.g., Si₁₋ₓCₓ, or Si₁₋ₓGeₓ, or the like). In some embodiments, the source/drain regions 218a and 218b can also be referred to as source/drain epitaxial structures.

An ILD layer 120 is formed over the substrate 105, covering the source/drain regions 218a and 218b, and laterally surrounding the dummy gate structures 130a, 130b, 130c, and 130d. In some embodiments, the ILD layer 120 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

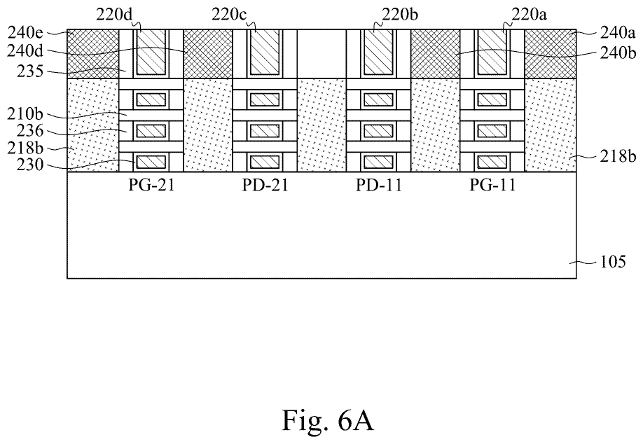

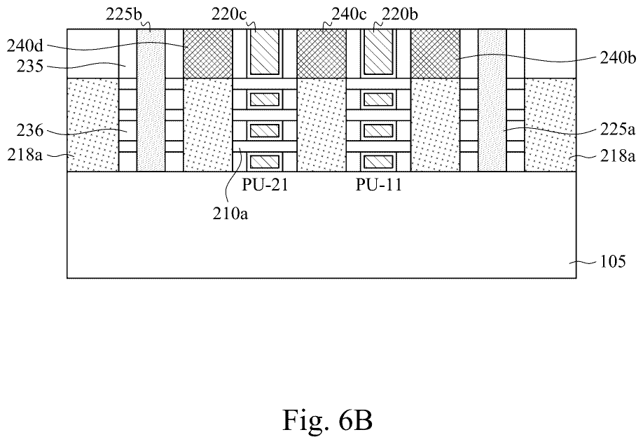

Reference is made to FIGS. 6A and 6B. The dummy gate structures 130a, 130b, 130c, and 130d are replaced with gate electrodes 220a, 220b, 220c and 220d, respectively. For example, the dummy gate structures 130a, 130b, 130c, and 130d may be removed, so as to form gate trenches between each pair of the gate spacers 235. The sacrificial layers 212 are removed through the gate trenches, such that the semiconductor layers 210 are suspended over the substrate 100. Gate dielectric layers 230 are formed in the gate trenches and wrapping around the respective semiconductor layers 210. The gate electrodes 220a, 220b, 220c and 220d are then formed over the gate dielectric layers 230 and wrapping around the respective semiconductor layers 210.

In FIGS. 6A and 6B, the dielectric gates 225a and 225b may also be formed. In some embodiments, the dielectric gates 225a and 225b may be formed by, for example, prior to replacing the dummy gate structures 130a, 130b, 130c, and 130d with the gate electrodes 220a, 220b, 220c and 220d, replacing portions of the dummy gate structures 130a and 130d and portions of the underlying semiconductor layers 210 and the sacrificial layers 212 with a dielectric material. In other embodiments, the dielectric gates 225a and 225b may be formed by, for example, after replacing the dummy gate structures 130a, 130b, 130c, and 130d with the gate electrodes 220a, 220b, 220c and 220d, replacing portions of the gate electrodes 220a and 220d and portions of the underlying semiconductor layers 210 with a dielectric material.

In some embodiments, the gate dielectric layer 230 of the gate electrodes 220a and 220d may be made of a high-k dielectric material. Examples of high-k dielectric material include aluminum oxide (Al₂O₃), hafnium oxide (HfO₂), titanium oxide (TiO₂), zirconium oxide (ZrO₂), other suitable high-k dielectric materials, and/or combinations thereof. In some embodiments, each of the gate electrodes 220a and 220d may include a work function metal layer and a filling metal over the work function metal layer. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

Although not shown in FIGS. 6A and 6B, it is understood that the gate electrodes 220e to 220h as discussed in FIGS. 2A to 2D may also be formed using the same method and may include the same material as described in FIGS. 4A to 6B. Similarly, although not shown in FIGS. 6A and 6B, it is understood that the dielectric gates 225c and 225d as discussed in FIGS. 2A to 2D may also be formed using the same method and may include the same material as described in FIGS. 4A to 6B.

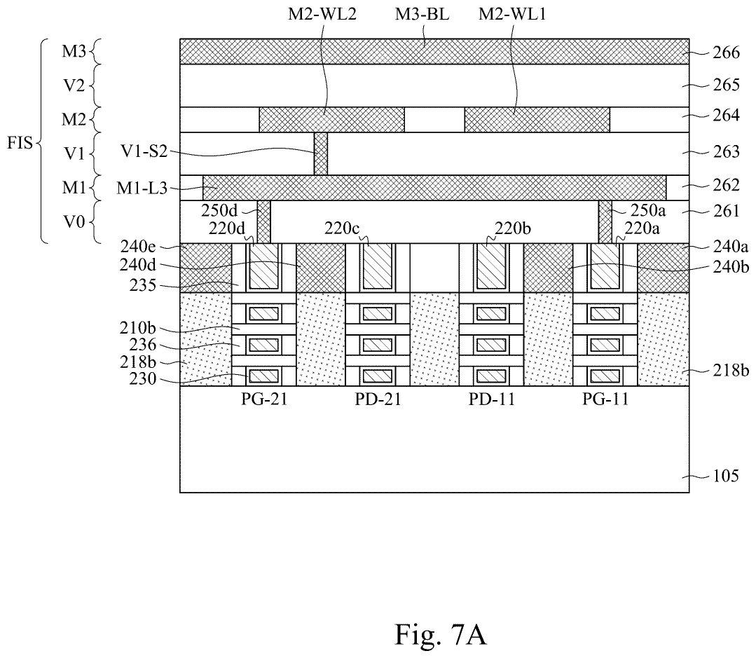

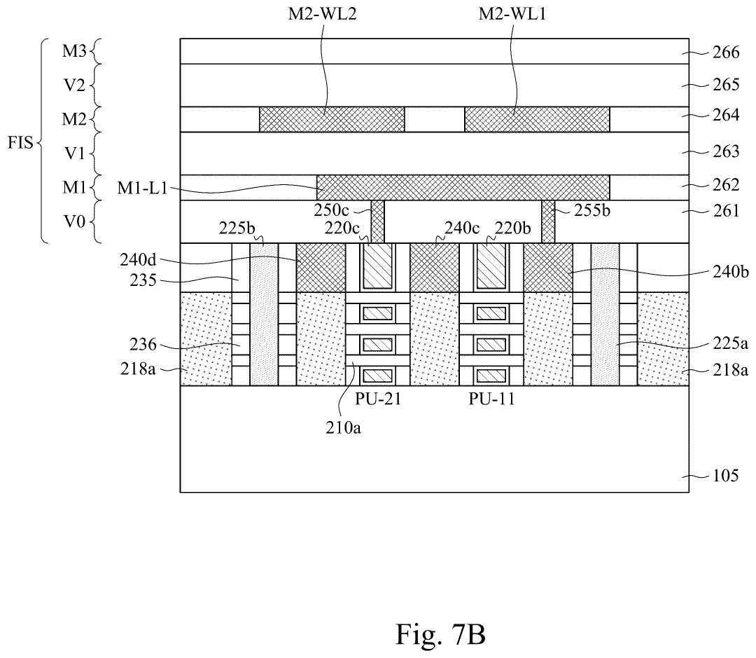

Reference is made to FIGS. 7A and 7B. A front-side interconnect structure FIS is formed over the ILD layer 120. With respect to the layer V0, a dielectric layer 261 is deposited over the ILD layer 120 and is patterned to form several openings, and conductive materials are formed in the openings of the dielectric layer 261 to form the gate vias 250a to 250h and the source/drain vias 255a to 255h. With respect to the layer M1, a dielectric layer 262 is deposited over the dielectric layer 261 and is patterned to form several openings, and conductive materials are formed in the openings of the dielectric layer 262 to form the metal lines M1-Vdd1, M1-L1, M1-L2, M1-L3, M1-BL1, M1-BL2, M1-L4, M1-L5, M1-L6, and M1-Vdd2. With respect to the layer V1, a dielectric layer 263 is deposited over the dielectric layer 262 and is patterned to form several openings, and conductive materials are formed in the openings of the dielectric layer 263 to form the metal vias V1-S1, V1-S2, V1-S3, and V1-S4. With respect to the layer M2, a dielectric layer 264 is deposited over the dielectric layer 263 and is patterned to form several openings, and conductive materials are formed in the openings of the dielectric layer 264 to form the metal lines M2-L1, M2-WL1, M2-WL2, and M2-L2. With respect to the layer V2, a dielectric layer 265 is deposited over the dielectric layer 264 and is patterned to form several openings, and conductive materials are formed in the openings of the dielectric layer 265 to form the metal vias V2-S1 and V2-S2. With respect to the layer M3, a dielectric layer 266 is deposited over the dielectric layer 265 and is patterned to form several openings, and conductive materials are formed in the openings of the dielectric layer 266 to form the metal lines M3-BL and M3-BLB.

In some embodiments, the dielectric layers 261 to 266 may include may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The conductive materials for the metal lines or metal vias may include suitable conductive material, such as Cu, Co, Ru, Pt, Al, W, Ti, TaN, TiN, or any combinations thereof.

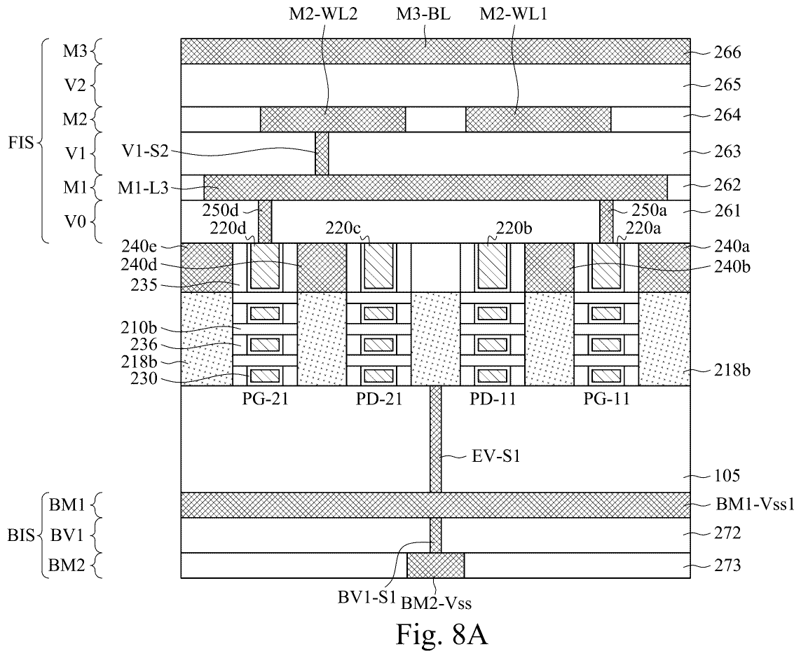

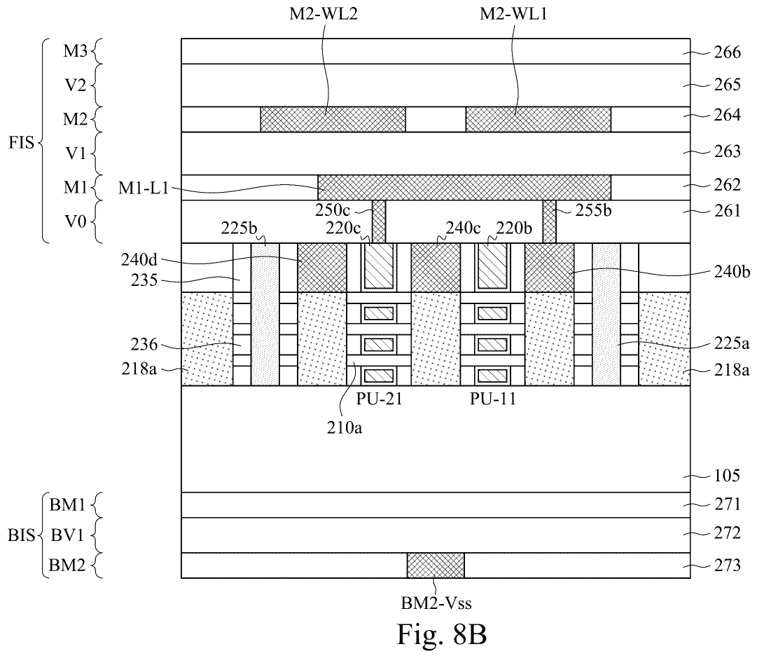

Reference is made to FIGS. 8A and 8B. After the front-side interconnect structure FIS are formed, metal vias EV-S1 and EV-S2 may be formed in the substrate 105. In some embodiments, the substrate 105 may be flipped over by, for example, 180 degrees, such that the backside of the substrate 105 faces upwardly. The substrate 105 may be patterned to form openings from the backside of the substrate 105 to expose the corresponding source/drain regions (e.g., the source/drain regions 218b). Then, conductive materials are formed in the openings to form the metal vias EV-S1 and EV-S2.

Afterwards, a back-side interconnect structure BIS is formed over the backside of the substrate 105. With respect to the layer BM1, a dielectric layer 271 is deposited over the backside of the substrate 105 and is patterned to form several openings, and conductive materials are formed in the openings of the dielectric layer 271 to form the metal lines BM1-Vss1 and BM1-Vss2. With respect to the layer BV1, a dielectric layer 272 is deposited over the dielectric layer 271 and is patterned to form several openings, and conductive materials are formed in the openings of the dielectric layer 272 to form the metal vias BV1-S1 and BV1-S2. With respect to the layer BM2, a dielectric layer 273 is deposited over the dielectric layer 272 and is patterned to form several openings, and conductive materials are formed in the openings of the dielectric layer 273 to form the metal line BM2-Vss.

In some embodiments, the dielectric layers 271 to 273 may include may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The conductive materials for the metal lines or metal vias may include suitable conductive material, such as Cu, Co, Ru, Pt, Al, W, Ti, TaN, TiN, or any combinations thereof.

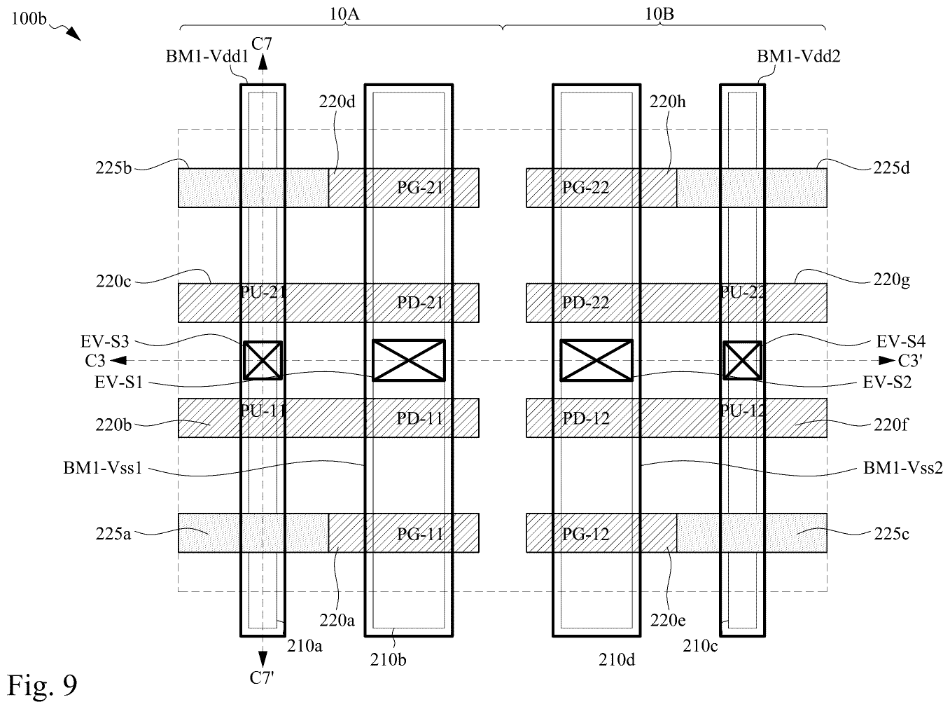

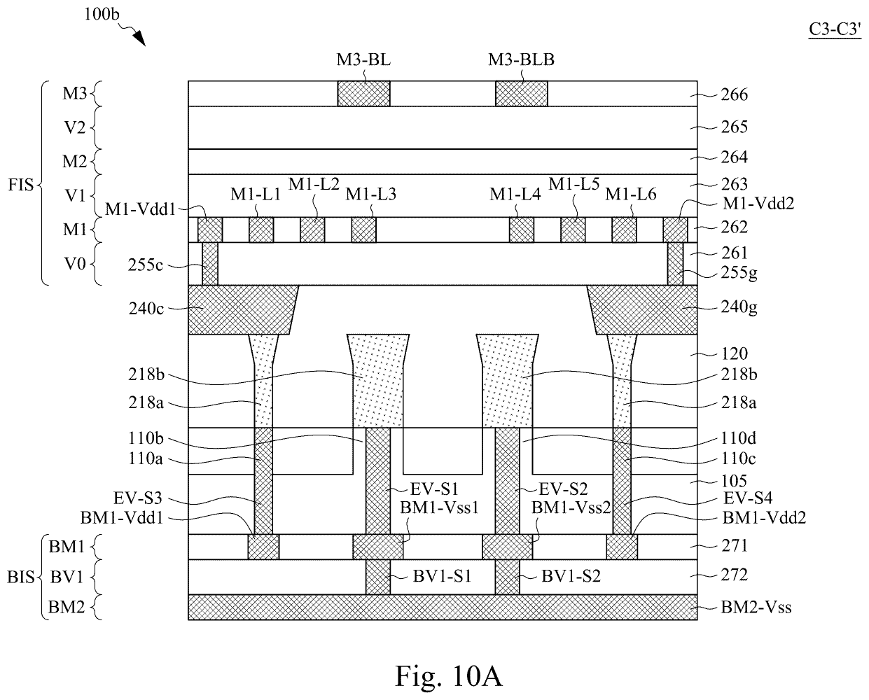

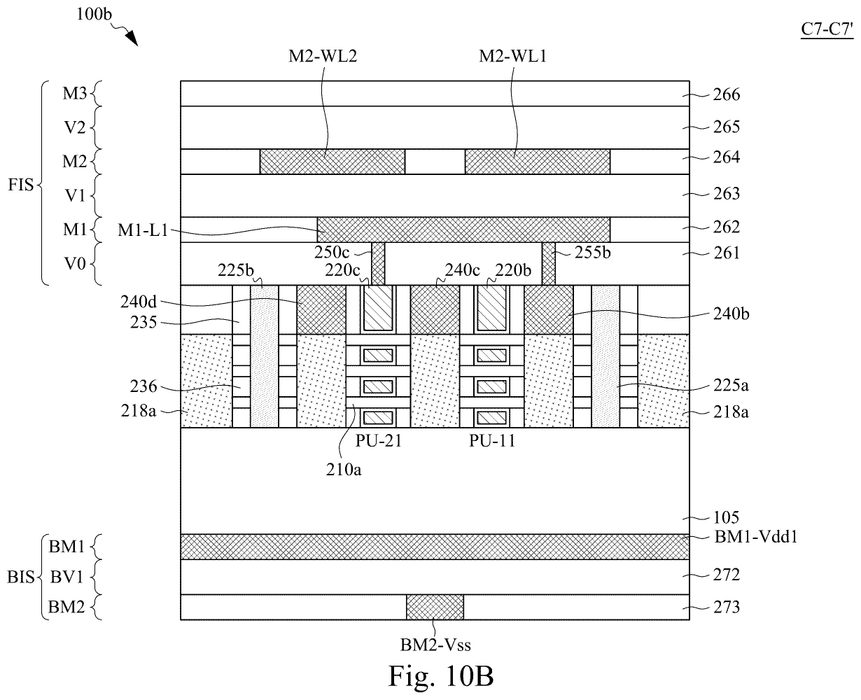

FIG. 9 illustrates a layout of a memory device, in accordance with some embodiments of the present disclosure. FIGS. 10A and 10B illustrate cross-sectional views along reference cross-sections C3-C3′ and C7-C7′ in FIG. 9, respectively. In FIGS. 9 and 10A to 10B, shown there is a memory device 100b. The memory device 100b may be similar to the memory device 100a as discussed above with respect to FIGS. 2A to 2D and 3A to 3H, similar elements will be labeled the same, and relevant details will not be repeated for brevity. FIG. 9 illustrates a layout that is similar to the layout of FIG. 2C, and FIGS. 10A and 10B illustrate cross-sectional views that are similar to the cross-sectional views of FIGS. 3C and 3G, respectively.

The memory device 100b further includes metal vias EV-S3 and EV-S4 in the substrate 105, which are at the same level as the metal vias EV-S1 and EV-S2. The metal via EV-S3 is electrically coupled with the source/drain regions of the transistors PU-11 and PU-21. The metal via EV-S4 is electrically coupled with the source/drain regions of the transistors PU-12 and PU-22. The metal vias EV-S3 and EV-S4 can be formed together with the metal vias EV-S1 and EV-S2 as described above.

The memory device 100b further includes metal lines BM1-Vdd1 and BM1-Vdd2 at the layer BM1 of the back-side interconnect structure BIS. The metal line BM1-Vdd1 and BM1-Vdd2 are electrically connected with the metal vias EV-S1 and EV-S2. Accordingly, the metal line BM1-Vdd1 can be electrically coupled to the source/drain regions (e.g., the source/drain regions 218a) of the transistors PU-11 and PU-21. Similarly, the metal line BM1-Vdd2 can be electrically coupled to the source/drain regions (e.g., the source/drain regions 218a) of the transistors PU-12 and PU-22. The metal lines BM1-Vdd1 and BM1-Vdd2 can be formed together with the BM1-Vss1 and BM1-Vss2 as discussed above.

In some embodiments, the metal line BM1-Vdd1 may also serve as the power rail VDD of the memory cell 10A, and the metal line BM1-Vdd2 may also serve as the power rail VDD of the memory cell 10B. Accordingly, the metal lines BM1-Vdd1 and BM1-Vdd2 can also be referred to as power rails BM1-Vdd1 and BM1-Vdd2. Each of the metal lines BM1-Vdd1 and BM1-Vdd2 may include a lengthwise direction extending along the Y-direction. In some embodiments, each of the metal lines M1-Vdd1 and M1-Vdd2 may include a length that is greater than the cell height H1 of the memory cells 10A and 10B.

In the embodiments of FIGS. 9 and 10A to 10B, the power rail VDD of the memory cell 10A (e.g., the metal line M1-Vdd1 and the metal line BM1-Vdd1) can be arranged on both sides of the substrate 105, and the power rail VDD of the memory cell 10B (e.g., metal line M1-Vdd2 and metal line BM1-Vdd2) can be arranged on both sides of the substrate 105.

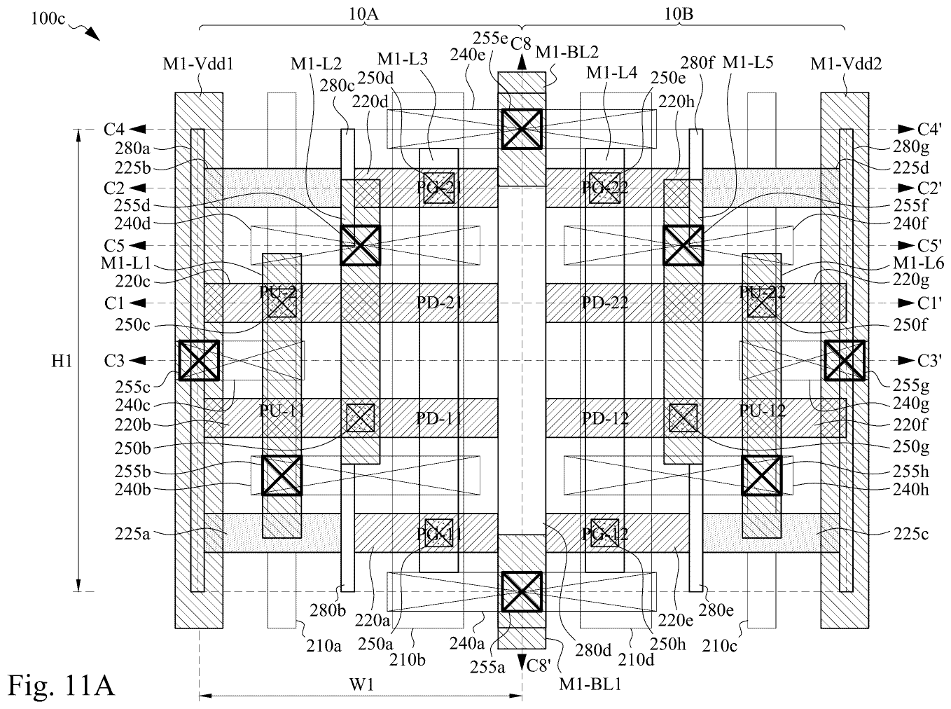

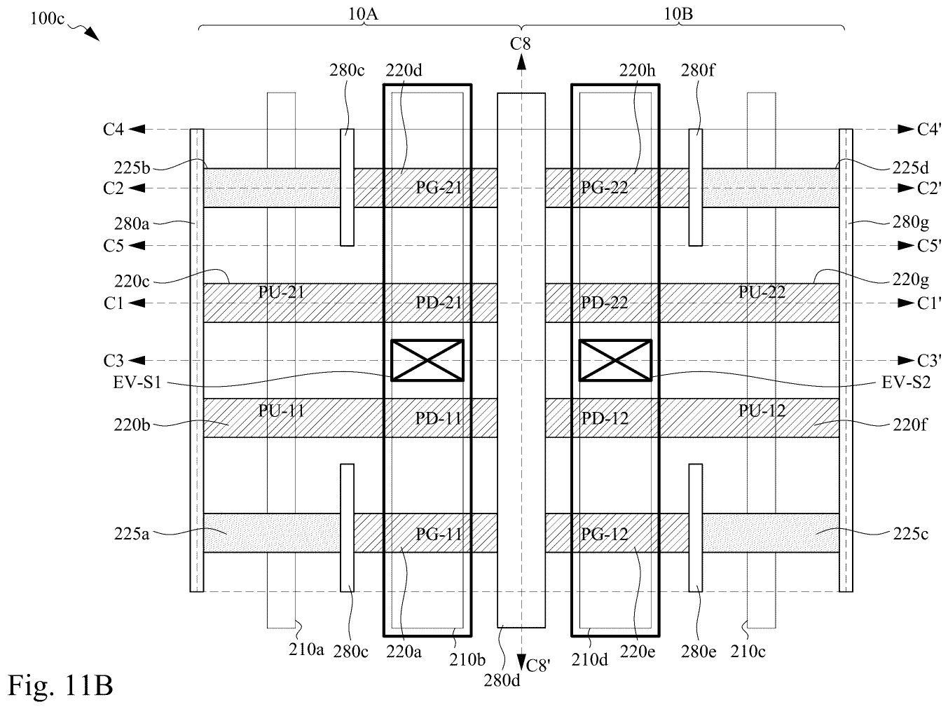

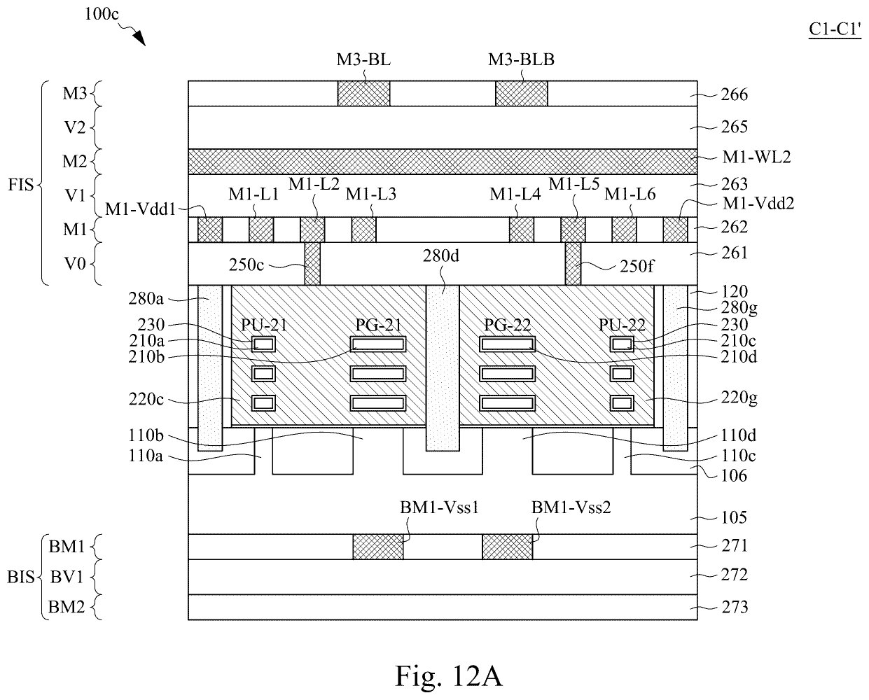

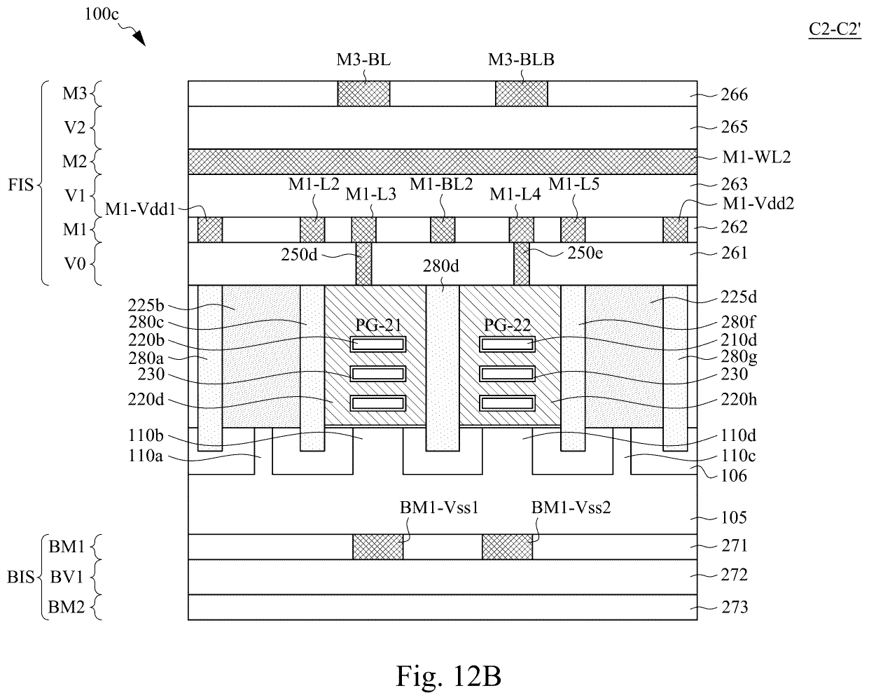

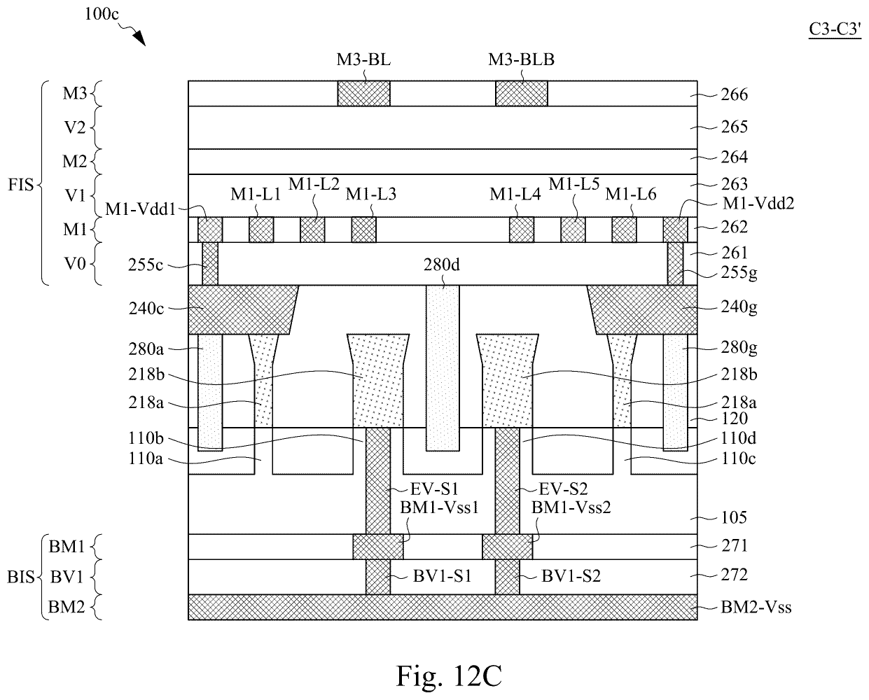

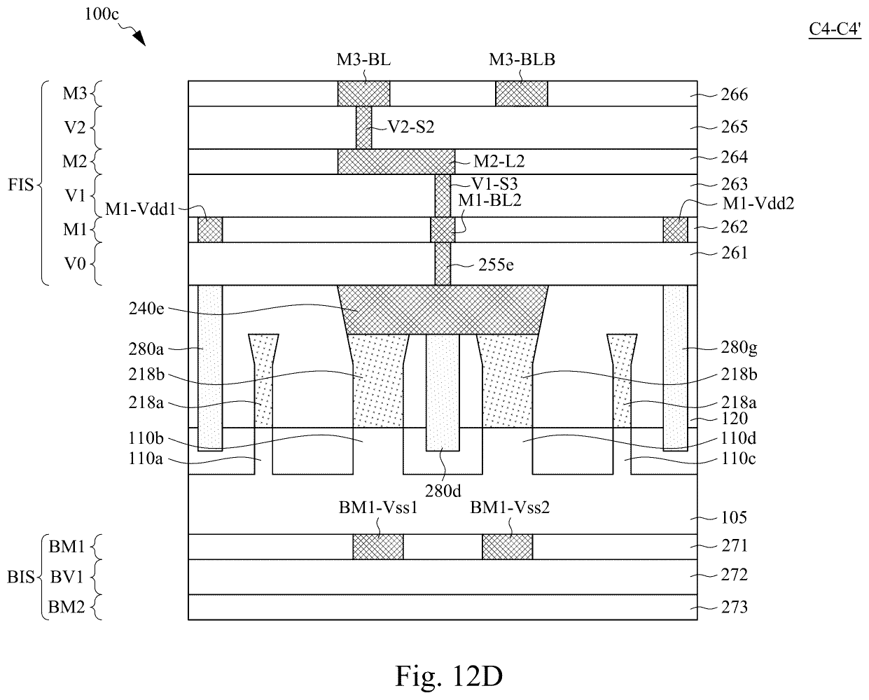

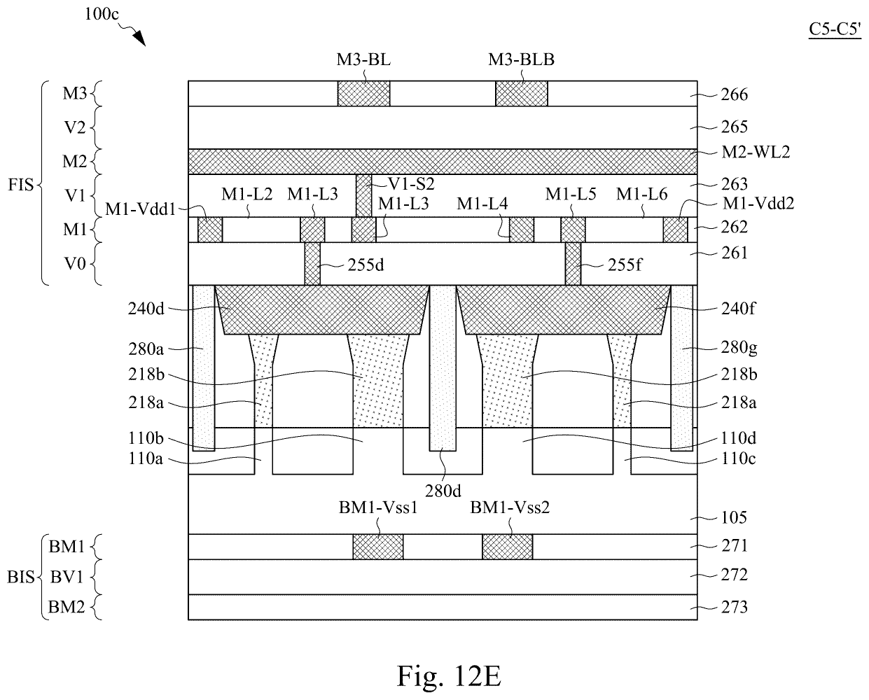

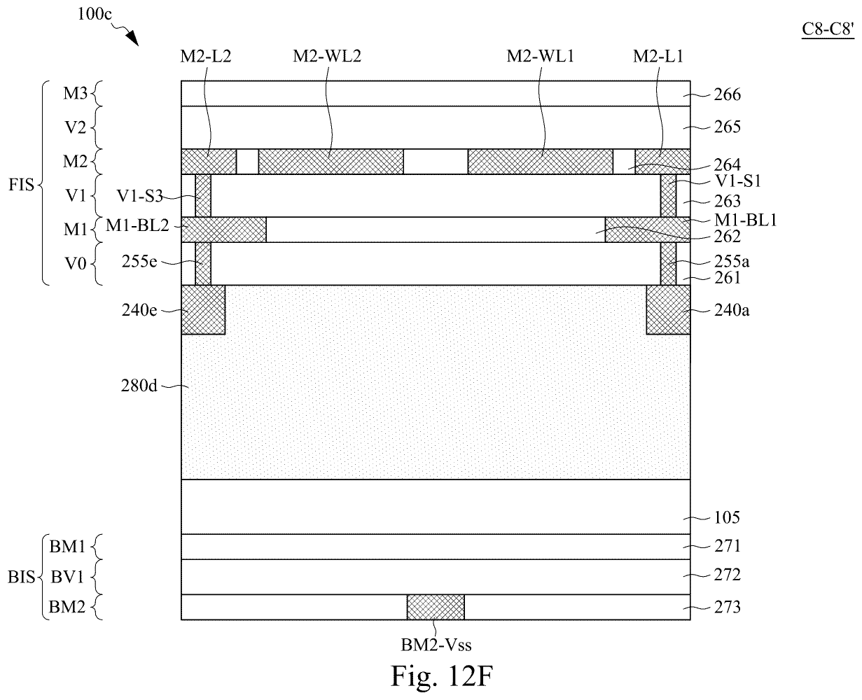

FIGS. 11A and 11B illustrate a layout of a memory device, in accordance with some embodiments of the present disclosure. FIGS. 12A to 12F illustrate cross-sectional views along reference cross-sections C1-C1′, C2-C2′, C3-C3′, C4-C4′, C5-C5′, and C8-C8′ in FIGS. 11A and 11B, respectively. In FIGS. 11A to 11B and 12A to 12F, shown there is a memory device 100c. The memory device 100c may be similar to the memory device 100a as discussed above with respect to FIGS. 2A to 2D and 3A to 3H, similar elements will be labeled the same, and relevant details will not be repeated for brevity. FIGS. 11A and 11B illustrate a layout that is similar to the layout of FIGS. 2A and 2C, respectively. FIGS. 12A, 12B, 12C, 12D, 12E, and 12F illustrate cross-sectional views that are similar to the cross-sectional views of FIGS. 3A, 3B, 3C, 3D, 3E, and 3F, respectively.

The memory device 100c further includes gate-end dielectrics 280a, 280b, 280c, 280d, 280e, 280f, and 280g extending along the Y-direction. The gate-end dielectric 280a is in contact with the longitudinal ends of the gate electrodes 220b and 220c and the dielectric gates 225a and 225b. The gate-end dielectric 280b is in contact with the longitudinal ends of the gate electrode 220a and the dielectric gate 225a. The gate-end dielectric 280c is in contact with the longitudinal ends of the gate electrode 220d and the dielectric gate 225b. The gate-end dielectric 280d is in contact with the longitudinal ends of the gate electrodes 220a, 220b, 220c, 220d, 220e, 220f, 220g, and 220h. In some embodiments, the gate-end dielectric 280d may be located on the boundary of the memory cells 10A and 10B. The gate-end dielectric 280e is in contact with the longitudinal ends of the gate electrode 220e and the dielectric gate 225c. The gate-end dielectric 280f is in contact with the longitudinal ends of the gate electrode 220h and the dielectric gate 225d. The gate-end dielectric 280g is in contact with the longitudinal ends of the gate electrodes 220f and 220g and the dielectric gates 225c and 225d. In some embodiments, the gate-end dielectrics 280a to 280g can be made of silicon oxide (SiOx), silicon nitride (SixNy), silicon oxynitride (SiON), dielectric material(s), other suitable material, or a combination thereof.

As shown in the cross-sectional views of FIGS. 12A to 12F, the bottom of the gate-end dielectrics 280a to 280g may extend to the respective isolation structures 106. The top surfaces of the gate-end dielectrics 280a to 280g may be substantially level with top surfaces of the gate electrodes 220a to 220h. The gate-end dielectrics 280a to 280g can be formed using suitable process. For example, after the gate electrodes 220f and 220g are formed, the structure over the substrate 105 can be patterned to form openings in the structure that define the position and the profile of the gate-end dielectrics 280a to 280g, and then forming dielectric materials in the openings to form the gate-end dielectrics 280a to 280g.

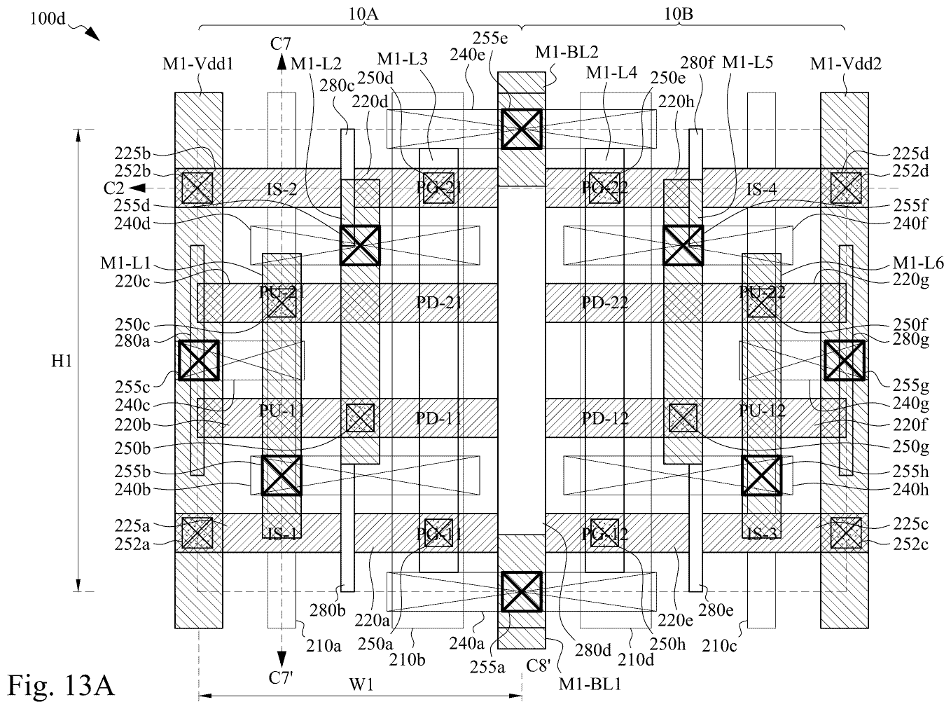

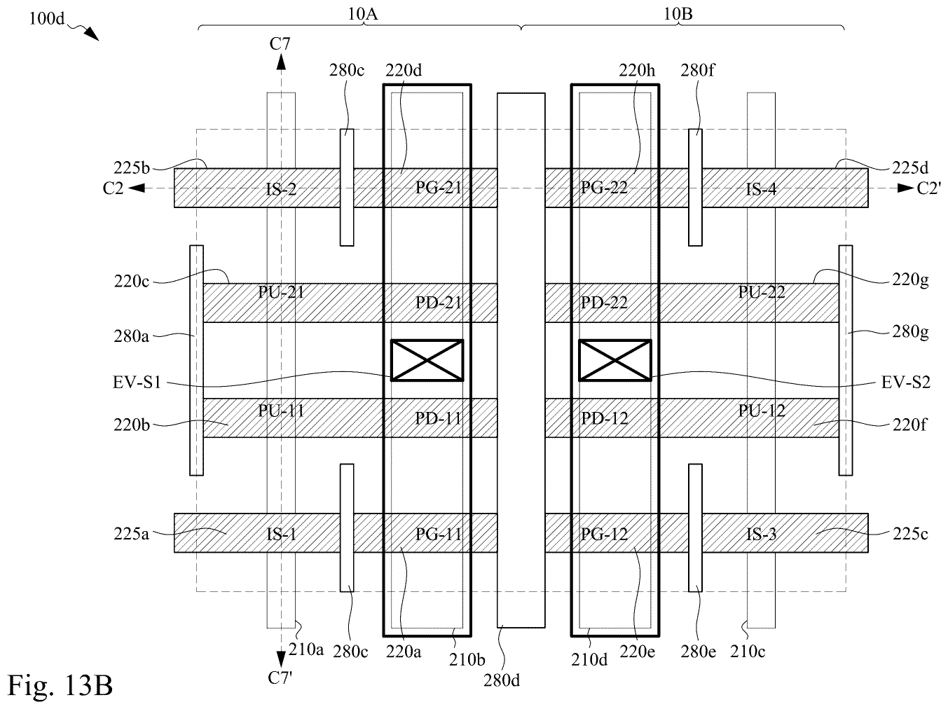

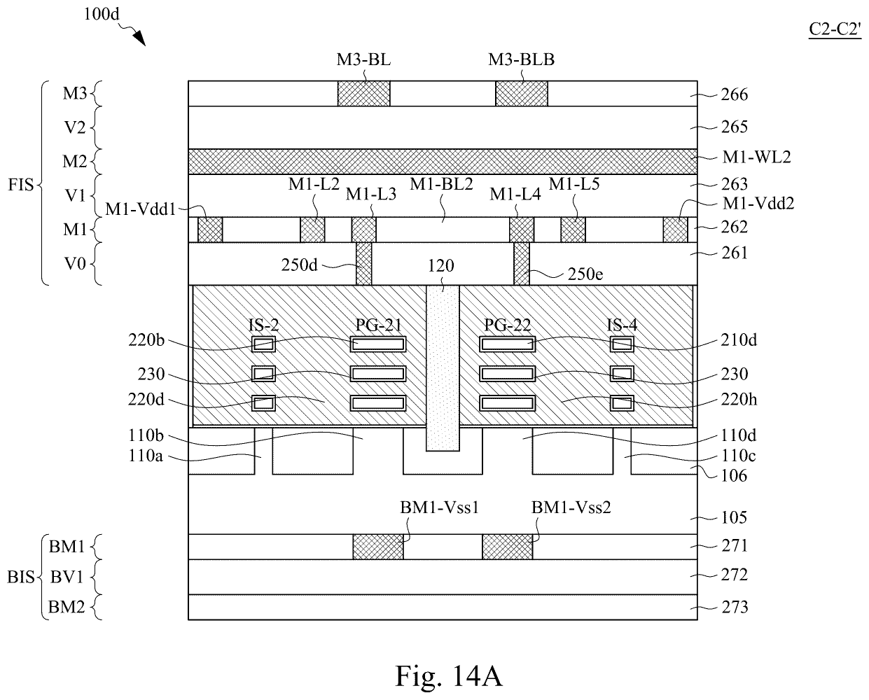

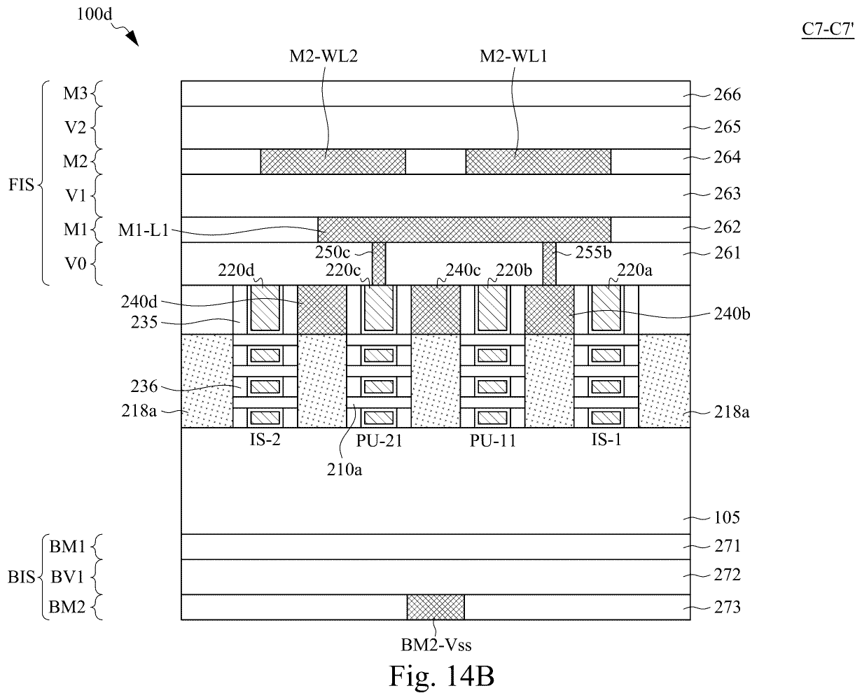

FIGS. 13A and 13B illustrate a layout of a memory device, in accordance with some embodiments of the present disclosure. FIGS. 14A and 14B illustrate cross-sectional views along reference cross-sections C2-C2′ and C7-C7′ in FIGS. 13A and 13B, respectively. In FIGS. 13A to 13B and 14A to 14B, shown there is a memory device 100d. The memory device 100d may be similar to the memory device 100a as discussed above with respect to FIGS. 2A to 2D and 3A to 3H, similar elements will be labeled the same, and relevant details will not be repeated for brevity. FIGS. 13A and 13B illustrate a layout that is similar to the layout of FIGS. 2A and 2C, respectively. FIGS. 14A and 14B illustrate cross-sectional views that are similar to the cross-sectional views of FIGS. 3B and 3G, respectively.

The memory device 100d further includes transistors IS-1, IS-2, IS-3, and IS-4, in which the transistors IS-1 and IS-2 are disposed in the memory cell 10A, and the transistors IS-3 and IS-4 are disposed in the memory cell 10B. In some embodiments, the transistors IS-1 and IS-2 are not a part of the SRAM device in the memory cell 10A, and the transistors IS-3 and IS-4 are not a part of the SRAM device in the memory cell 10B. In some embodiments, the transistors IS-1, IS-2, IS-3, and IS-4 can also be referred to as isolation (IS) devices.

With respect to the transistor IS-1, the transistor IS-1 includes semiconductor layers 210a, a gate electrode 222a wrapping around the semiconductor layers 210a, and source/drain regions 218a on opposite sides of the gate electrode 222a. With respect to the transistor IS-2, the transistor IS-2 includes semiconductor layers 210a, a gate electrode 222b wrapping around the semiconductor layers 210a, and source/drain regions 218a on opposite sides of the gate electrode 222a. With respect to the transistor IS-3, the transistor IS-3 includes semiconductor layers 210c, a gate electrode 222c wrapping around the semiconductor layers 210c, and source/drain regions on opposite sides of the gate electrode 222c. With respect to the transistor IS-4, the transistor IS-4 includes semiconductor layers 210c, a gate electrode 222d wrapping around the semiconductor layers 210c, and source/drain regions on opposite sides of the gate electrode 222d.

The memory device 100d further includes gate vias 252a, 252b, 252c, and 250d at the layer V0 of the front-side interconnect structure FIS. The gate via 252a may electrically connect the gate electrode 222a of the transistor IS-1 to the metal line M1-Vdd1. The gate via 252b may electrically connect the gate electrode 222b of the transistor IS-2 to the metal line M1-Vdd1. The gate via 252c may electrically connect the gate electrode 222c of the transistor IS-3 to the metal line M1-Vdd2. The gate via 252d may electrically connect the gate electrode 222d of the transistor IS-4 to the metal line M1-Vdd2.

The memory device 100d further includes gate-end dielectrics 280a, 280b, 280c, 280d, 280e, 280f, and 280g extending along the Y-direction. The gate-end dielectric 280a is in contact with the longitudinal ends of the gate electrodes 220b and 220c. The gate-end dielectric 280b is in contact with the longitudinal ends of the gate electrodes 220a and 222a. The gate-end dielectric 280c is in contact with the longitudinal ends of the gate electrodes 220d and 222b. The gate-end dielectric 280d is in contact with the longitudinal ends of the gate electrodes 220a, 220b, 220c, 220d, 220e, 220f, 220g, and 220h. In some embodiments, the gate-end dielectric 280d may be located on the boundary of the memory cells 10A and 10B. The gate-end dielectric 280e is in contact with the longitudinal ends of the gate electrodes 220e and 222c. The gate-end dielectric 280f is in contact with the longitudinal ends of the gate electrodes 220h and 222d. The gate-end dielectric 280g is in contact with the longitudinal ends of the gate electrodes 220f and 220g.

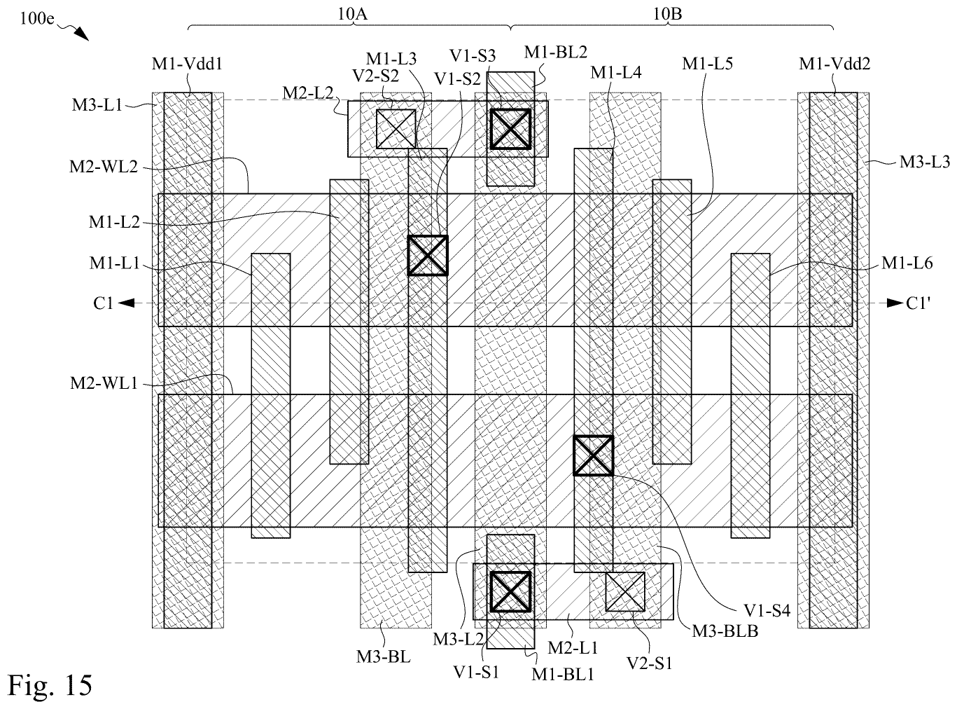

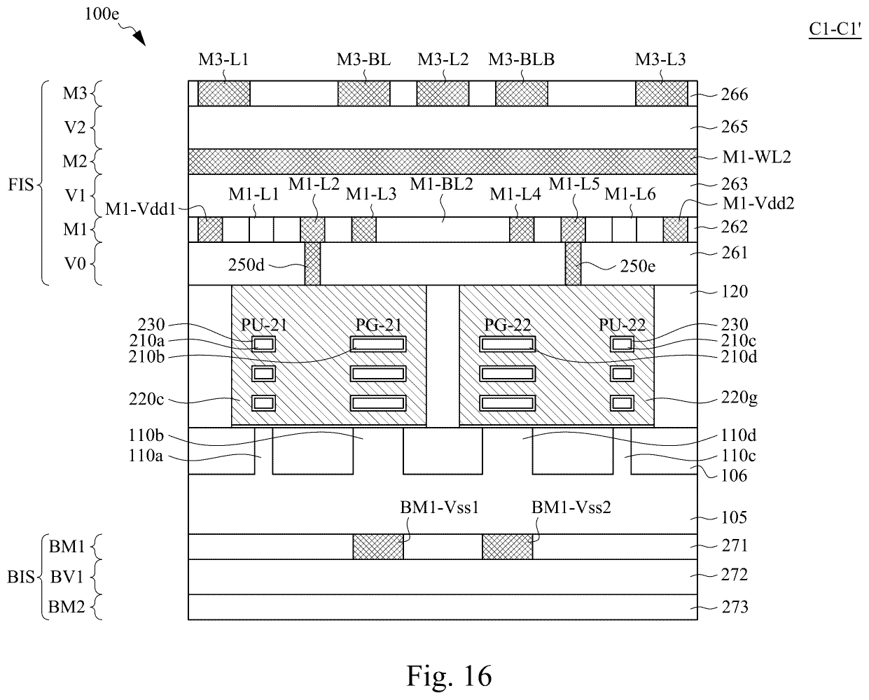

FIG. 15 illustrates a layout of a memory device, in accordance with some embodiments of the present disclosure. FIG. 16 illustrates a cross-sectional view along reference cross-section C1-C1′ in FIG. 15. In FIGS. 15 and 16, shown there is a memory device 100e. The memory device 100e may be similar to the memory device 100a as discussed above with respect to FIGS. 2A to 2D and 3A to 3H, similar elements will be labeled the same, and relevant details will not be repeated for brevity. FIG. 15 illustrates a layout that is similar to the layout of FIG. 2B. FIG. 16 illustrates a cross-sectional view that is similar to the cross-sectional view of FIG. 3A.

The memory device 100e further includes metal lines M3-L1, M3-L2, and M3-L3 at the layer M3 of the front-side interconnect structure FIS. The metal line M3-BL is between the metal lines M3-L1 and M3-L2, and the metal line M3-BLB is between the metal lines M3-L2 and M3-L3. In some embodiments, the metal lines M3-L1, M3-L2, and M3-L3 can be formed together with the metal lines M3-BL and M3-BLB as discussed above.

In some embodiments, metal lines M3-L1, M3-L2, and M3-L3 can serve as the power rail VDD of the memory cell 10A and 10B. In such conditions, suitable routing in the front-side interconnect structure FIS can be applied, such that the metal lines M3-L1, M3-L2, and M3-L3 can be electrically connected with the source/drain regions of the transistors PU-11 and PU-21 of the memory cell 10A and the source/drain regions of the transistors PU-12 and PU-22 of the memory cell 10B. In some embodiments, the metal lines M3-L1 and M3-L3 can be omitted. In other embodiments, the metal line M3-L2 can be omitted.

In other embodiments, metal lines M3-L1, M3-L2, and M3-L3 can serve as the power rail VSS of the memory cell 10A and 10B. In such conditions, suitable routing in the front-side interconnect structure FIS can be applied, such that the metal lines M3-L1, M3-L2, and M3-L3 can be electrically connected with the source/drain regions of the transistors PD-11 and PD-21 of the memory cell 10A and the source/drain regions of the transistors PD-12 and PD-22 of the memory cell 10B. In some embodiments, the metal lines M3-L1 and M3-L3 can be omitted. In other embodiments, the metal line M3-L2 can be omitted.

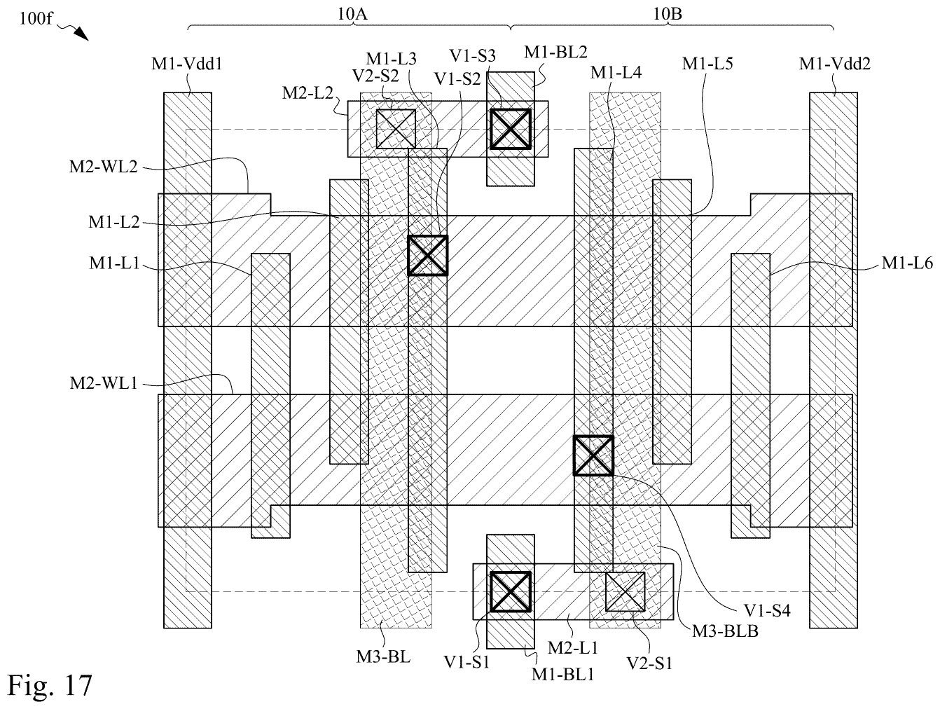

FIG. 17 illustrates a layout of a memory device, in accordance with some embodiments of the present disclosure. In FIG. 17, shown there is a memory device 100f. The memory device 100f may be similar to the memory device 100a as discussed above with respect to FIGS. 2A to 2D and 3A to 3H, similar elements will be labeled the same, and relevant details will not be repeated for brevity. FIG. 17 illustrates a layout that is similar to the layout of FIG. 2B.

In the memory device 100f, each of the metal lines M2-WL1 and M2-WL2 includes varying widths along the X-direction. For example, with respect to the metal line M2-WL1, along the X-direction, the metal line M2-WL1 may include a middle portion and edge portions on opposite sides of the middle portion, in which the edge portions are wider than the middle portion along the Y-direction. The metal line M2-WL2 may include a similar profile as the metal line M2-WL1. In some embodiments, each of the metal lines M2-WL1 and M2-WL2 may include a linear sidewall and a stepped sidewall opposite to the linear sidewall. In some embodiments, the linear sidewall of the metal line M2-WL1 may face the metal line M2-WL2, and the linear sidewall of the metal line M2-WL2 may face the metal line M2-WL1.

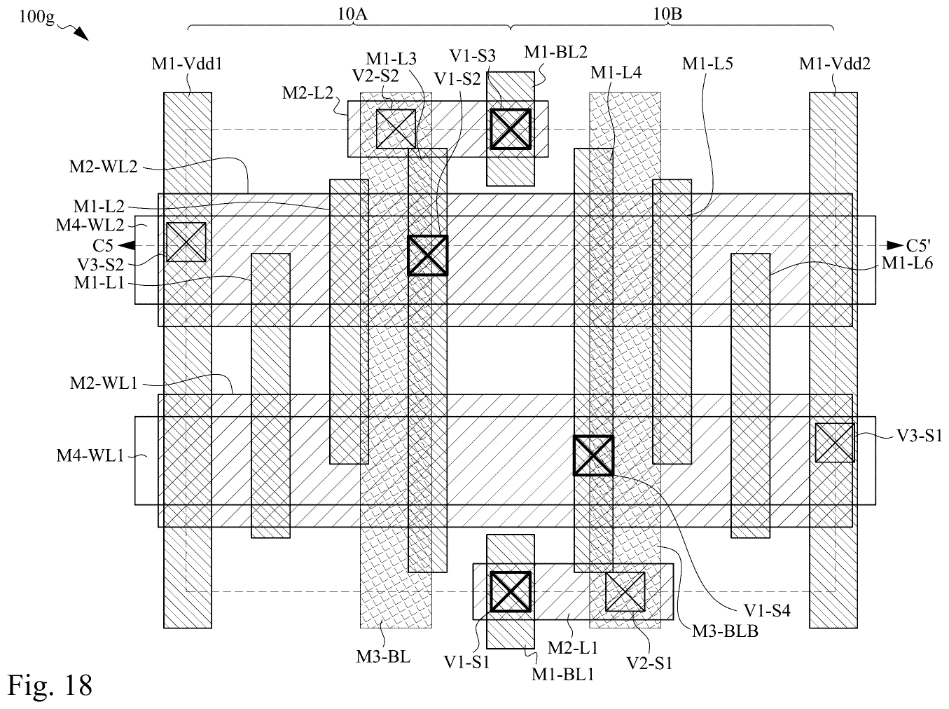

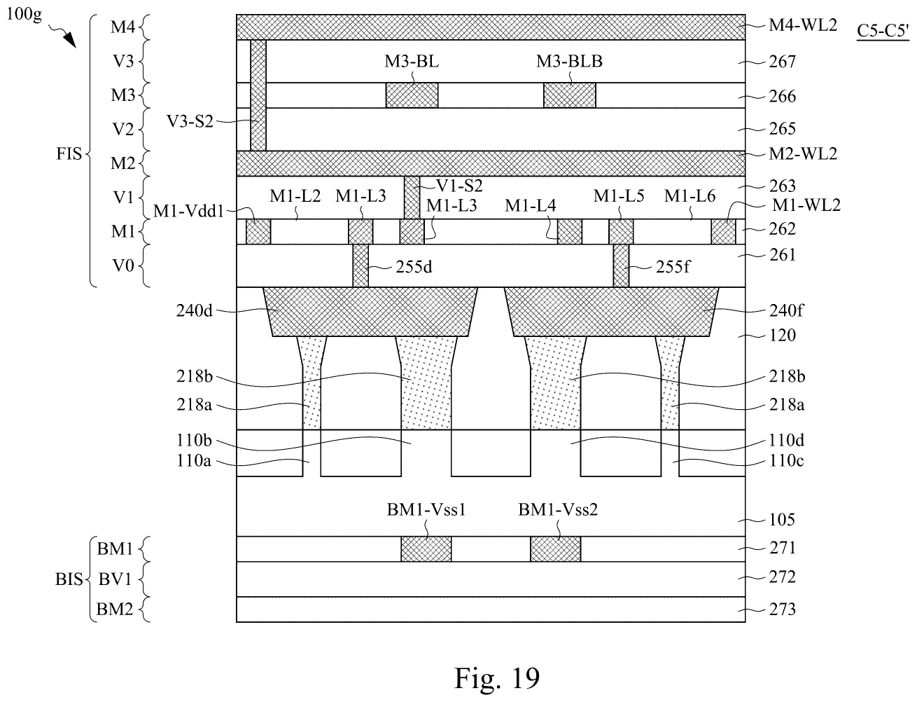

FIG. 18 illustrates a layout of a memory device, in accordance with some embodiments of the present disclosure. FIG. 19 illustrates a cross-sectional view along reference cross-sections C5-C5′ in FIG. 18. In FIGS. 18 and 19, shown there is a memory device 100g. The memory device 100g may be similar to the memory device 100a as discussed above with respect to FIGS. 2A to 2D and 3A to 3H, similar elements will be labeled the same, and relevant details will not be repeated for brevity. FIG. 18 illustrates a layout that is similar to the layout of FIG. 2B. FIG. 19 illustrates a cross-sectional view that is similar to the cross-sectional view of FIG. 3E.

The memory device 100g further includes metal lines M4-WL1 and M4-WL2 above the metal lines M3-BL and M3-BLB. The metal line M4-WL1 may be electrically connected with the metal line M2-WL1 through a conductive feature V3-S1, and the metal line M4-WL2 may be electrically connected with the metal line M2-WL2 through a conductive feature V3-S2.

In some embodiments, the metal lines M2-WL1 and M4-WL1 may collectively serve as the word line WL of the memory cell 10A, and the metal lines M2-WL2 and M4-WL2 may collectively serve as the word line WL of the memory cell 10B. Accordingly, the metal lines M2-WL1 and M4-WL1 can be collectively referred to as a word line structure, and the metal lines M2-WL2 and M4-WL2 can be collectively referred to as a word line structure. Each of the metal lines M4-WL1 and M4-WL2 may include a lengthwise direction extending along the X-direction. In some embodiments, each of the metal lines M4-WL1 and M4-WL2 may include a length that is greater than the twice the cell width W1 of the memory cells 10A and 10B. In some embodiments, the each of the metal lines M4-WL1 and M4-WL2 may overlap both the memory cells 10A and 10B. In some embodiments, the metal lines M4-WL1 overlaps the metal lines M2-WL1, and the metal lines M4-WL2 overlaps the metal lines M2-WL2.

As shown in FIG. 19, the front-side interconnect structure FIS further includes a layer V3 over the layer M3, and a layer M4 over the layer V3. The layers V3 and M4 may include dielectric layers, respectively. For example, in FIG. 19, the layer V3 includes a dielectric layer 267. In some embodiments, the metal lines M4-WL1 and M4-WL2 are present in the layer M4. In some embodiments, the metal lines M4-WL1 and M4-WL2 can be electrically connected with the underlying metal lines M2-WL1 and M2-WL2 through the conductive features V3-S1 and V3-S2. In some embodiments, the conductive features V3-S1 and V3-S2 may extend through the layers V2, M3, and V3. The conductive features V3-S1 and V3-S2 each may be a metal via or a combination of metal line and metal via.

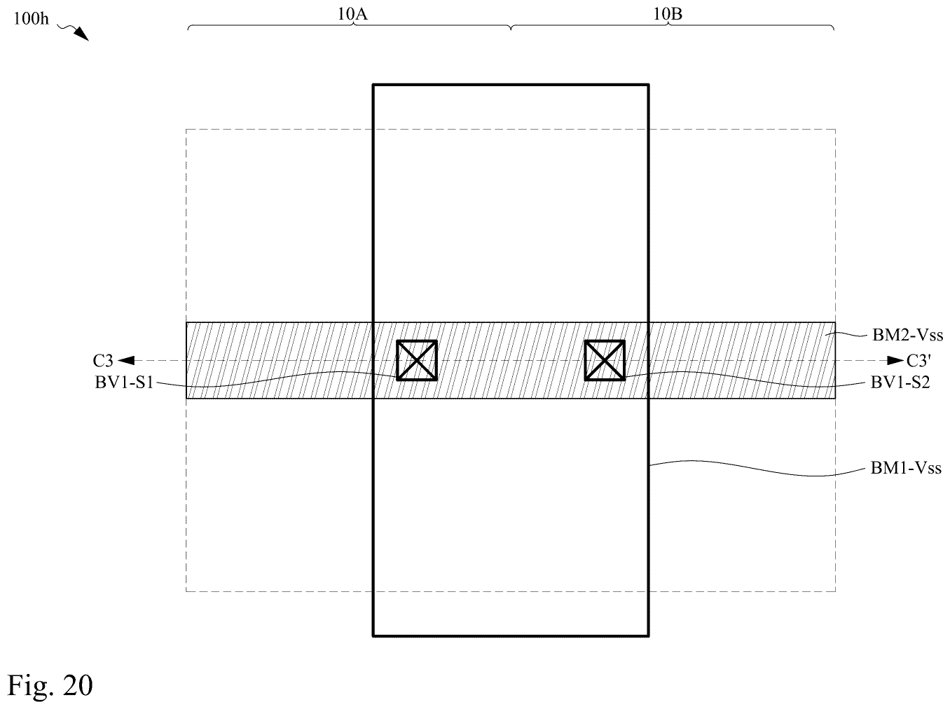

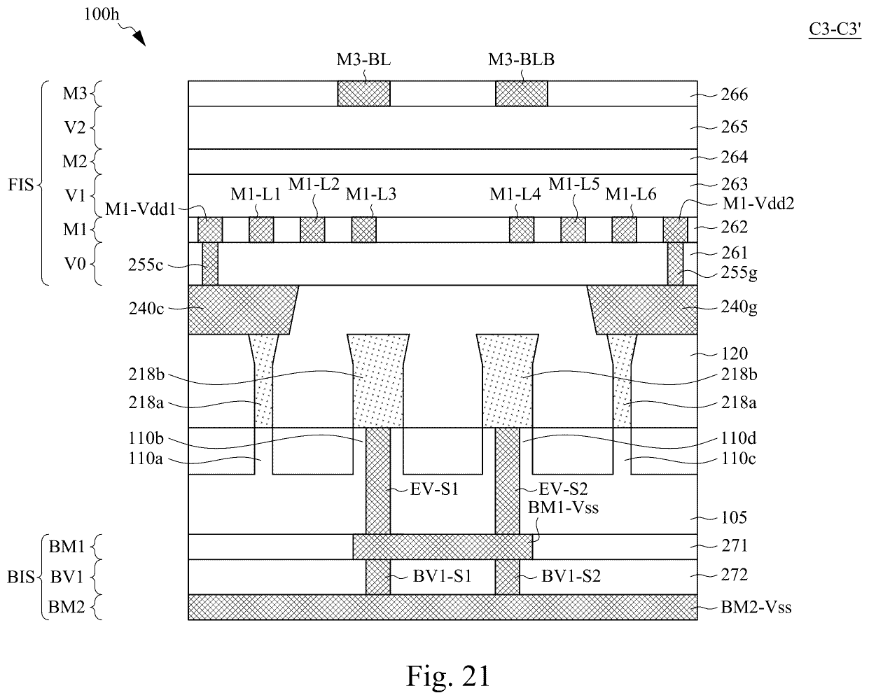

FIG. 20 illustrates a layout of a memory device, in accordance with some embodiments of the present disclosure. FIG. 21 illustrates a cross-sectional view along reference cross-sections C3-C3′ in FIG. 20. In FIGS. 20 and 21, shown there is a memory device 100h. The memory device 100h may be similar to the memory device 100a as discussed above with respect to FIGS. 2A to 2D and 3A to 3H, similar elements will be labeled the same, and relevant details will not be repeated for brevity. FIG. 20 illustrates a layout that is similar to the layout of FIG. 2D. FIG. 21 illustrates a cross-sectional view that is similar to the cross-sectional view of FIG. 3C.

In the memory device 100h, there is a single metal line BM1-Vss in the layer BM1 of the back-side interconnect structure BIS. The metal line BM1-Vss is electrically connected to the metal line BM2-Vss through the metal vias BV1-S1 and BV1-S2. In some embodiments, the metal line BM1-Vss may serve as the power rails VSS of the memory cell 10A and 10B. In some embodiments, a ground line (e.g., OV) may be applied to the metal line BM2-Vss, and thus the metal lines BM1-Vss can also be referred to as ground line BM1-Vss. In some embodiments, the metal line BM2-Vss may include a lengthwise direction extending along the Y-direction. In some embodiments, the metal line BM2-Vss may include a length that is greater than the cell height H1 of the memory cells 10A and 10B. In some embodiments, the metal line BM2-Vss may overlaps both the memory cells 10A and 10B.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a memory device by arranging two memory cells along a first direction. The memory device further includes a bit line and a complementary bit line extending along a second direction perpendicular to the first direction, in which the bit line is electrically connected with both two memory cells, and the complementary bit line is electrically connected with both two memory cells. The merged two memory cells with one bit-line pair allows for a wider width for the bit line, which in turn allows for a decrease in resistance and an increase in array size for capacitance reduction.

In some embodiments of the present disclosure, a memory device comprises a substrate, a first memory cell, a second memory cell, a bit line, and a complementary bit line. The first memory cell and the second memory cell are over the substrate and are arranged along a first direction. The first memory cell and the second memory cell each comprises a first pull-up transistor, a first pull-down transistor, a first pass-gate transistor, a second pull-up transistor, a second pull-down transistor, and a second pass-gate transistor. The first pull-down transistor, the first pass-gate transistor, the second pull-down transistor, and the second pass-gate transistor are arranged along a second direction substantially perpendicular to the first direction. The bit line is electrically connected with both the first memory cell and the second memory cell. The complementary bit line is electrically connected with both the first memory cell and the second memory cell.

In some embodiments, the bit line and the complementary bit line each includes a lengthwise direction along the second direction.

In some embodiments, the bit line and the complementary bit line are arranged along the first direction.

In some embodiments, the bit line overlaps the first memory cell and the complementary bit line overlaps the second memory cell.

In some embodiments, the bit line overlaps the a first pull-down transistor, the first pass-gate transistor, the second pull-down transistor, and the second pass-gate transistor of the first memory cell.

In some embodiments, the memory device further includes a first word line electrically connected with the first memory cell, and a second word line electrically connected with the second memory cell, in which the first word line and the second word line are below the bit line and the complementary bit line.

In some embodiments, the memory device further includes a first power rail electrically connected with the first memory cell, and a second power rail electrically connected with the second memory cell, in which the first power rail and the second power rail are below the first word line and the second word line.

In some embodiments, the memory device further includes a ground line at a back side of the substrate and electrically connected with both the first memory cell and the second memory cell.

In some embodiments, a gate electrode of the first pull-down transistor of the first memory cell is aligned with a gate electrode of the first pull-down transistor of the second memory cell along the first direction. A gate electrode of the first pass-gate transistor of the first memory cell is aligned with a gate electrode of the first pass-gate transistor of the second memory cell along the first direction.

In some embodiments of the present disclosure, a memory device comprises a substrate, a first static random access memory (SRAM) cell, a second SRAM cell, a bit line, and a complementary bit line. The first SRAM cell and the second SRAM cell are over the substrate and arranged along a first direction. The bit line overlaps the first SRAM cell and is electrically connected with both the first SRAM cell and the second SRAM cell. The complementary bit line overlaps the second SRAM cell and is electrically connected with both the first SRAM cell and the second SRAM cell. The bit line and the complementary bit line each includes a lengthwise direction along a second direction substantially perpendicular to the first direction.

In some embodiments, the memory device further includes a first word line overlapping both the first SRAM cell and the second SRAM cell and electrically connected with the first SRAM cell, and a second word line overlapping both the first SRAM cell and the second SRAM cell and electrically connected with the second SRAM cell.

In some embodiments, the first word line has a varying width along the first direction.

In some embodiments, the memory device further includes a first power rail electrically connected with the first SRAM cell, and a second power rail electrically connected with the second SRAM cell, in which the first power rail and the second power rail are below the bit line and the complementary bit line.

In some embodiments, the memory device further includes a ground line in contact with a bottom surface of the substrate and electrically connected with both the first SRAM cell and the second SRAM cell.

In some embodiments, the ground line overlaps both the first SRAM cell and the second SRAM cell.

In some embodiments of the present disclosure, a method includes forming a first static random access memory (SRAM) cell and a second SRAM cell over a front side of a substrate and arranged along a first direction; forming a front-side interconnect structure over the first SRAM cell and the second SRAM cell, wherein a first layer of the front-side interconnect structure comprises a bit line electrically connected with both the first SRAM cell and the second SRAM cell; and a complementary bit line electrically connected with both the first SRAM cell and the second SRAM cell; and forming a back-side interconnect structure over a back side of the substrate and electrically connected with the first SRAM cell and the second SRAM cell.

In some embodiments, the front-side interconnect structure further includes a second layer below the first layer. The second layer includes a first word line overlapping both the first SRAM cell and the second SRAM cell and electrically connected with the first SRAM cell, and a second word line overlapping both the first SRAM cell and the second SRAM cell and electrically connected with the second SRAM cell, wherein the second layer is lower than the first layer.

In some embodiments, the front-side interconnect structure further includes a third layer below the second layer. The third layer includes a first power rail electrically connected with the first SRAM cell, and a second power rail electrically connected with the second SRAM cell.

In some embodiments, the method further includes forming metal vias in the substrate prior to forming the back-side interconnect structure, wherein the back-side interconnect structure is electrically connected with the first SRAM cell and the second SRAM cell through the metal vias.

In some embodiments, the back-side interconnect structure includes a ground line.

In some embodiments of the present disclosure, a semiconductor structure includes a substrate, a first cell and a second cell over the substrate, a first metal line, and a second metal line. The first cell and the second cell are over the substrate and arranged along a first direction, wherein the first cell comprises first transistors arranged along a second direction substantially perpendicular to the first direction, and the second cell comprises second transistors arranged along the second direction, and wherein gate structures of the first transistors and gate structures of the second transistors extend along the first direction. The first metal line is electrically connected with a source/drain region of a first one of the first transistors and a source/drain region of a first one of the second transistors. A second metal line is electrically connected with a source/drain region of a second one of the first transistors and a source/drain region of a second one of the second transistors.

In some embodiments, the first metal line and the second metal line each includes a lengthwise direction along the second direction.

In some embodiments, the first metal line and the second metal line are arranged along the first direction.

In some embodiments, the first metal line overlaps the first cell and the second metal line overlaps the second cell.

In some embodiments, the first metal line overlaps at least parts of the gate structures the first transistors.

In some embodiments, the semiconductor structure further includes a third metal line electrically connected with the gate structures of the first one and the second one of the first transistors. A fourth metal line is electrically connected with the gate structures of the first one and the second one of the second transistors, wherein the third metal line and the fourth metal line are below the first metal line and the second metal line.

In some embodiments, the semiconductor structure further includes a first power rail electrically connected with the first transistors of the first cell. A second power rail is electrically connected with the second transistors of the second cell, wherein the first power rail and the second power rail are below the third metal line and the fourth metal line.

In some embodiments, the semiconductor structure further includes a backside metal line at a backside of the substrate and electrically connected with the first transistors of the first cell and the second transistors of the second cell.

In some embodiments, one of the gate structures of the first transistors is aligned with one of the gate structures of the second transistors along the first direction.

In some embodiments of the present disclosure, a semiconductor structure includes a semiconductor structure includes a substrate, a first cell and a second cell over the substrate, a first metal line, a second metal line, and a backside metal line. The first cell and the second cell are over the substrate and arranged along a first direction, wherein the first cell comprises first transistors and the second cell comprises second transistors. The first metal line overlaps the first cell and is electrically connected with a source/drain region of a first one of the first transistors and a source/drain region of a first one of the second transistors. The second metal line overlaps the second cell and is electrically connected with a source/drain region of a second one of the first transistors and a source/drain region of a second one of the second transistors, and wherein the first metal line and the second metal line each includes a lengthwise direction along a second direction substantially perpendicular to the first direction. The backside metal line is at a backside of the substrate and is electrically connected with the first transistors of the first cell and the second transistors of the second cell.

In some embodiments, the semiconductor structure further includes a third metal line overlapping both the first cell and the second cell and electrically connected with gate structures of the first one and the second one of the first transistors. A fourth metal word line overlaps both the first cell and the second cell and electrically connected with gate structures of the first one and the second one of the second transistors.

In some embodiments, the third metal line has a varying width along the first direction.

In some embodiments, the semiconductor structure further includes a first power rail electrically connected with the first transistors of the first cell. A second power rail is electrically connected with the second transistors of the second cell, wherein the first power rail and the second power rail are below the first metal line and the second metal line.

In some embodiments, the backside metal line is a ground line.

In some embodiments, the backside metal line overlaps both the first cell and the second cell.

In some embodiments of the present disclosure, a method includes forming a first cell and a second cell over a front side of a substrate and arranged along a first direction, wherein the first cell comprises first transistors and the second cell comprises second transistors; forming a front-side interconnect structure over the first cell and the second cell, wherein a first layer of the front-side interconnect structure comprises a first metal line overlapping the first cell and electrically connected with a source/drain region of a first one of the first transistors and a source/drain region of a first one of the second transistors; and a second metal line overlapping the second cell and electrically connected with a source/drain region of a second one of the first transistors and a source/drain region of a second one of the second transistors; and forming a back-side interconnect structure over a back side of the substrate and electrically connected with the first cell and the second cell.

In some embodiments, the front-side interconnect structure further includes a second layer below the first layer. The second layer includes a third metal line overlapping both the first cell and the second cell and electrically connected with gate structures of the first one and the second one of the first transistors, and a fourth metal word line overlapping both the first cell and the second cell and electrically connected with gate structures of the first one and the second one of the second transistors.

In some embodiments, the front-side interconnect structure further includes a third layer below the second layer. The third layer includes a first power rail electrically connected with the first cell, and a second power rail electrically connected with the second cell.

In some embodiments, the method further includes forming metal vias in the substrate prior to forming the back-side interconnect structure, wherein the back-side interconnect structure is electrically connected with the first cell and the second cell through the metal vias.

In some embodiments, the back-side interconnect structure comprises a ground line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a first cell and a second cell over the substrate and arranged along a first direction, wherein the first cell comprises first transistors arranged along a second direction substantially perpendicular to the first direction, and the second cell comprises second transistors arranged along the second direction, and wherein gate structures of the first transistors and gate structures of the second transistors extend along the first direction;
a first metal line electrically connected with a source/drain region of a first one of the first transistors and a source/drain region of a first one of the second transistors; and
a second metal line electrically connected with a source/drain region of a second one of the first transistors and a source/drain region of a second one of the second transistors.

2. The semiconductor structure of claim 1, wherein the first metal line and the second metal line each includes a lengthwise direction along the second direction.

3. The semiconductor structure of claim 2, wherein the first metal line and the second metal line are arranged along the first direction.

4. The semiconductor structure of claim 1, wherein the first metal line overlaps the first cell and the second metal line overlaps the second cell.

5. The semiconductor structure of claim 1, wherein the first metal line overlaps at least parts of the gate structures the first transistors.

6. The semiconductor structure of claim 1, further comprising:
a third metal line electrically connected with the gate structures of the first one and the second one of the first transistors; and
a fourth metal line electrically connected with the gate structures of the first one and the second one of the second transistors, wherein the third metal line and the fourth metal line are below the first metal line and the second metal line.

7. The semiconductor structure of claim 6, further comprising:
a first power rail electrically connected with the first transistors of the first cell; and
a second power rail electrically connected with the second transistors of the second cell, wherein the first power rail and the second power rail are below the third metal line and the fourth metal line.

8. The semiconductor structure of claim 7, further comprising a backside metal line at a backside of the substrate and electrically connected with the first transistors of the first cell and the second transistors of the second cell.

9. The semiconductor structure of claim 1, wherein one of the gate structures of the first transistors is aligned with one of the gate structures of the second transistors along the first direction.

10. A semiconductor structure, comprising:
a substrate;
a first cell and a second cell over the substrate and arranged along a first direction, wherein the first cell comprises first transistors and the second cell comprises second transistors;
a first metal line overlapping the first cell and electrically connected with a source/drain region of a first one of the first transistors and a source/drain region of a first one of the second transistors;
a second metal line overlapping the second cell and electrically connected with a source/drain region of a second one of the first transistors and a source/drain region of a second one of the second transistors, and wherein the first metal line and the second metal line each includes a lengthwise direction along a second direction substantially perpendicular to the first direction; and
a backside metal line at a backside of the substrate and electrically connected with the first transistors of the first cell and the second transistors of the second cell.

11. The semiconductor structure of claim 10, further comprising:
a third metal line overlapping both the first cell and the second cell and electrically connected with gate structures of the first one and the second one of the first transistors; and
a fourth metal word line overlapping both the first cell and the second cell and electrically connected with gate structures of the first one and the second one of the second transistors.

12. The semiconductor structure of claim 11, wherein the third metal line has a varying width along the first direction.

13. The semiconductor structure of claim 10, further comprising:
a first power rail electrically connected with the first transistors of the first cell; and
a second power rail electrically connected with the second transistors of the second cell, wherein the first power rail and the second power rail are below the first metal line and the second metal line.

14. The semiconductor structure of claim 10, wherein the backside metal line is a ground line.

15. The semiconductor structure of claim 10, wherein the backside metal line overlaps both the first cell and the second cell.

16. A method, comprising:
forming a first cell and a second cell over a front side of a substrate and arranged along a first direction, wherein the first cell comprises first transistors and the second cell comprises second transistors;
forming a front-side interconnect structure over the first cell and the second cell, wherein a first layer of the front-side interconnect structure comprises:
a first metal line overlapping the first cell and electrically connected with a source/drain region of a first one of the first transistors and a source/drain region of a first one of the second transistors; and
a second metal line overlapping the second cell and electrically connected with a source/drain region of a second one of the first transistors and a source/drain region of a second one of the second transistors; and
forming a back-side interconnect structure over a backside of the substrate and electrically connected with the first cell and the second cell.

17. The method of claim 16, wherein the front-side interconnect structure further comprises a second layer below the first layer, the second layer comprising:
a third metal line overlapping both the first cell and the second cell and electrically connected with gate structures of the first one and the second one of the first transistors; and
a fourth metal word line overlapping both the first cell and the second cell and electrically connected with gate structures of the first one and the second one of the second transistors.

18. The method of claim 17, wherein the front-side interconnect structure further comprises a third layer below the second layer, the third layer comprising:
a first power rail electrically connected with the first cell; and
a second power rail electrically connected with the second cell.

19. The method of claim 16, further comprising forming metal vias in the substrate prior to forming the back-side interconnect structure, wherein the back-side interconnect structure is electrically connected with the first cell and the second cell through the metal vias.

20. The method of claim 19, wherein the back-side interconnect structure comprises a ground line.
